(19) United States
(12) Patent Application Publication
(10) Pub. No.: US 2025/0280695 A1
(43) Pub. Date: Sep. 4, 2025

(54) TRANSPARENT DISPLAY DEVICE

(71) Applicant: LG Display Co., Ltd., Seoul (KR)

(72) Inventors: Taehee KO, Paju-si (KR); Dojin KIM, Paju-si (KR); Binn KIM, Paju-si (KR); JongSung KIM, Paju-si (KR)

(73) Assignee: LG Display Co., Ltd., Seoul (KR)

(21) Appl. No.: 19/058,721

(22) Filed: Feb. 20, 2025

(30) Foreign Application Priority Data
Feb. 29, 2024 (KR) 10-2024-0030138
Dec. 30, 2024 (KR) 10-2024-0201441

(51) Int. Cl. H10K 59/38; H10K 59/122; H10K 59/80

(52) U.S. Cl. CPC H10K 59/38; H10K 59/122; H10K 59/8792

(57) ABSTRACT

A transparent display device can include a substrate having a transmissive area and a non-transmissive area, a first light emitting area disposed on the non-transmissive area, a first color filter disposed in the non-transmissive area and corresponding to the first light emitting area, a step area disposed at a boundary area between the transmissive area and the non-transmissive area, and a first color compensation layer disposed in the transmissive area to overlap the step area.

### CROSS-REFERENCE TO RELATED APPLICATIONS

This application claims priority to Korean Patent Application No. 10-2024-0030138 filed in the Republic of Korea on Feb. 29, 2024, and Korean Patent Application No. 10-2024-0201441 filed in the Republic of Korea on Dec. 30, 2024, the entire contents of all these applications being hereby expressly incorporated by reference into the present application.

### BACKGROUND

### Technical Field

The present disclosure relates to a transparent display device with an improved display quality.

### Discussion of the Related Art

As an information society develops, demands for a display device for displaying an image are increasing in various forms. Accordingly, various display devices such as a liquid crystal display (LCD), a plasma display (PDP), and an organic light emitting display (OLED) have recently been used.

Among the display devices, the organic light emitting display device is a self-emission type and has excellent viewing angle and contrast ratio compared to the liquid crystal display (LCD). In addition, since a separate backlight is not required, light weight and thinness are possible, and power consumption is advantageous. Furthermore, the organic light emitting display device has advantages of being able to drive a DC low voltage, a fast response speed, and particularly low manufacturing cost.

An organic light emitting display device has a structure in which an organic light emitting device including a light emitting layer is provided between a cathode for injecting electrons and an anode for injecting holes. An organic light emitting display device is a display device using the principle that when electrons generated from a cathode and holes generated from an anode are injected into an emission layer, the injected electrons and holes are combined to generate excitons, and the generated excitons fall from an excited state to a ground state and emit light.

By applying a transparent display panel, the transparent display device can improve aesthetics because it can be seen through the back like a general glass when the display device is not driven, and has a wide range of fields used and applied in various fields such as a display provided in a vehicle window and a display used in home appliances.

Meanwhile, a plurality of insulating layers, light emitting layers, and transparent electrodes can be provided in the transmissive area representing the transparent portion of the transparent display panel so that light passing through the transmissive area can turn yellowish, and a limitation in which the background of the rear surface is not clearly visible can be formed as diffraction occurs in the transmissive area. In this case, an issue of deteriorating visibility of the transparent display panel can occur.

### SUMMARY OF THE DISCLOSURE

The present disclosure has been made in view of the above problems and other limitations associated with the related art.

Accordingly, it is an object of the present disclosure to provide a transparent display device that prevents the yellowing of light passing through a transmission area and the blurring of a back surface due to diffraction of light by having a color compensation layer in the transmission area.

In accordance with an aspect of the present disclosure, the above and other objects can be accomplished by the provision of a transparent display device comprising a substrate including a transmissive area and a non-transmissive area, a first light emitting area disposed on the non-transmissive area, a first color filter disposed in the non-transmissive area and corresponding to the first light emitting area, a step area disposed in the transmissive area, and/or at a boundary area between the transmissive area and the non-transmissive area, and a first color compensation layer disposed in the transmissive area to overlap the step area.

Furthermore, the above and other objects can be accomplished by the provision of a transparent display device comprising a non-transmissive area including a first light emitting area and a second light emitting area, a transmissive area disposed on one side of the non-transmissive area and transmitting light, a first color filter disposed to correspond to the first light emitting area in the non-transmissive area, and a first color compensation layer overlapping at least a portion of the transmissive area, wherein the color compensation layer is disposed to have a transmittance of light in a wavelength range being equal to or greater than 380 nm and less than 500 nm is greater than a transmittance of light in a wavelength range being equal to or greater 500 nm and less than 780 nm, and the transmittance of light in the wavelength range equal to or greater than 380 nm and less than 500 nm is equal to or greater than 20%.

Furthermore, the above and other objects can be accomplished by the provision of transparent display device comprising a substrate including a transmissive area and a non-transmissive area, a first insulating layer disposed on the substrate, a bank disposed on the first insulating layer and defining a first light emitting area and a second light emitting area, a step area disposed at a boundary area between the transmissive area and the non-transmissive area and disposed by one end of the first insulating layer and one end of the bank, and a first color compensation layer disposed to overlap the step area and having a complementary color relationship with light passing through the transmission area, wherein the step area overlaps the transmissive area.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a perspective view schematically illustrating a transparent display device according to an embodiment of the present disclosure.

FIG. 2 is a plan view schematically showing a transparent display device according to an embodiment of the present disclosure.

FIG. 3 is a plan view, enlarging an area ‘A’ of FIG. 2, illustrating a transparent display device according to an embodiment of the present disclosure.

FIG. 4 is a plan view, enlarging an area ‘B’ of FIG. 3, illustrating a transparent display device according to an embodiment of the present disclosure.

FIG. 5 is a cross-sectional view, along line I-I′ of FIG. 4, illustrating a transparent display device according to an embodiment of the present disclosure.

FIG. 6 is a graph showing transmittance of a first color compensation layer provided in a transparent display device according to an embodiment of the present disclosure for each wavelength band.

FIG. 7 is a cross-sectional view, along line I-I′ of FIG. 4, illustrating a transparent display device according to another embodiment of the present disclosure.

FIG. 8 is a plan view, enlarging area ‘B’ of FIG. 3, illustrating a transparent display device according to another embodiment of the present disclosure.

FIG. 9 is a cross-sectional view, along line II-II′ of FIG. 8, illustrating a transparent display device according to another embodiment of the present disclosure.

FIG. 10 is a graph showing transmittance for each wavelength band at a boundary of any one light emitting area provided in a transparent display device according to another embodiment of the present disclosure.

FIG. 11 is a cross-sectional view, along line III-III′ of FIG. 8, illustrating a transparent display device according to another embodiment of the present disclosure.

FIG. 12 is a graph showing transmittance for each wavelength band at the boundary of any one light emitting area provided in a transparent display device according to another embodiment of the present disclosure.

FIG. 13 is a plan view, enlarging area ‘B’ of FIG. 3, illustrating a transparent display device according to another embodiment of the present disclosure.

FIG. 14 is a cross-sectional view, along line IV-IV′ of FIG. 13, illustrating a transparent display device according to another embodiment of the present disclosure.

FIG. 15 is a cross-sectional view, along line V-V′ of FIG. 13, illustrating a transparent display device according to another embodiment of the present disclosure.

FIG. 16 is a plan view, enlarging area ‘B’ of FIG. 3, illustrating a transparent display device according to another embodiment of the present disclosure.

FIG. 17 is a cross-sectional view, along line VI-VI′ of FIG. 16, illustrating a transparent display device according to another embodiment of the present disclosure.

FIG. 18 is a plan view, enlarging area ‘B’ of FIG. 3, illustrating a transparent display device according to another embodiment of the present disclosure.

FIG. 19 is a cross-sectional view, along line VII-VII′ of FIG. 18, illustrating a transparent display device according to another embodiment of the present disclosure.

FIG. 20 is a plan view, enlarging area ‘B’ of FIG. 3, illustrating a transparent display device according to another embodiment of the present disclosure.

FIG. 21 is a cross-sectional view, along line VIII-VIII′ of FIG. 20, illustrating a transparent display device according to another embodiment of the present disclosure.

FIG. 22 is a plan view, enlarging area ‘B’ of FIG. 3, illustrating a transparent display device according to another embodiment of the present disclosure.

FIG. 23 is a cross-sectional view, along line IX-IX′ of FIG. 20, illustrating a transparent display device according to another embodiment of the present disclosure.

### DETAILED DESCRIPTION OF THE EMBODIMENTS

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “include,” “comprise,” “have,” “contain,” “constitute,” and “include” described in the present specification are used, another part can also be present unless “only” is used. The terms in a singular form can include plural forms unless noted to the contrary.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In construing an element, the element is construed as including an error region although there is no explicit description thereof.

In describing a positional relationship, for example, when the positional order is described as “on,” “above,” “over,” “below,” “under,” “beside,” “beneath”, near,” “close to,” “adjacent to,” “on a side of,” and “next,” the case of no contact therebetween can be included, unless “just” or “direct” is used.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

If it is mentioned that a first element is positioned “on” a second element, it does not mean that the first element is essentially positioned above the second element in the figure. The upper part and the lower part of an object concerned can be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” “A,” “B,” “(a),” “(b),” etc. can be used herein to describe various elements, these elements should not be limited by these terms. These terms are only used to distinguish one element from another and may not define order or sequence. For example, a first element could be termed a second element, and, similarly, a second element could be termed a first element.

In addition, terms, such as first, second, A, B, (a), (b), or the like may be used herein when describing components of the present disclosure. Each of these terminologies is not used to define an essence, order, or sequence of a corresponding component but used merely to distinguish the corresponding component from other components. In the case that it is described that a certain structural element or layer is “connected”, “coupled”, “adhered” or “joined” to another structural element or layer, it is typically interpreted that another structural element or layer may be “connected”, “coupled”, “adhered” or “joined” to the structural element or layer directly or indirectly.

It should be understood that the term “at least one” includes all combinations related with any one item. For example, “at least one among a first element, a second element and a third element” can include all combinations of two or more elements selected from the first, second and third elements as well as each element of the first, second and third elements.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Features of various embodiments of the present disclosure can be partially or overall coupled to or combined with each other, and can be variously inter-operated with each other and driven technically. The embodiments of the present disclosure can be carried out independently from each other, or can be carried out together in a co-dependent relationship. Further, the term “can” encompasses all the meanings and coverages of the term “may.” The term “disclosure” is interchangeably used with, or encompasses all the meanings and coverages of, the term “invention.”

Unless otherwise defined, all terms (including technical and scientific terms) used herein have the same meaning as commonly understood by one of the ordinary skill in the art to which example embodiments belong. It will be further understood that terms, such as those defined in commonly used dictionaries, should be interpreted as having a meaning, for example consistent with their meaning in the context of the relevant art and should not be interpreted in an idealized or overly formal sense unless expressly so defined herein.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode can be the drain electrode, and the drain electrode can be the source electrode. Further, the source electrode in any one embodiment of the present disclosure can be the drain electrode in another embodiment of the present disclosure, and the drain electrode in any one embodiment of the present disclosure can be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region can be a source electrode, and a drain region can be a drain electrode. Further, a source region can be a drain electrode, and a drain region can be a source electrode. In addition, all the components of each display device or apparatus according to all embodiments of the present disclosure are operatively coupled and configured.

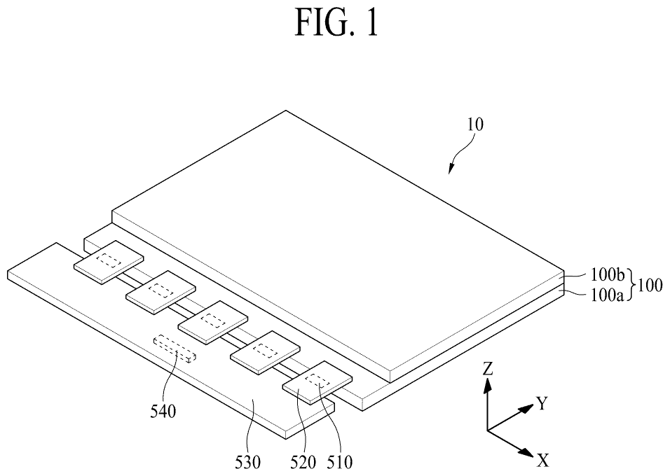

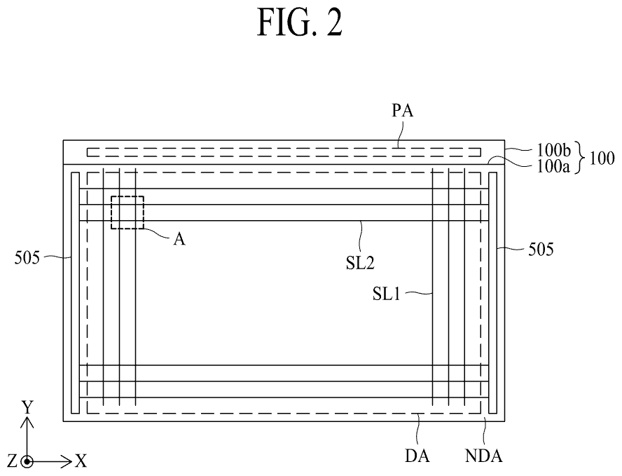

FIG. 1 is a perspective view schematically illustrating a transparent display device according to an embodiment of the present disclosure, and FIG. 2 is a plan view schematically showing a transparent display device according to an embodiment of the present disclosure.

Hereinafter, the X axis represents a direction parallel to the gate line, the Y axis represents a direction parallel to the data line, and the Z axis represents the height direction of a transparent display device 10.

Although the transparent display device 10 according to an embodiment of the present disclosure is mainly described as an organic light emitting transparent display, it can be implemented as a liquid crystal display LCD, a plasma display panel PDP, a quantum dot light emitting display QLED, or an electrophoretic transparent display.

Referring to FIGS. 1 and 2, the transparent display device 10 according to an embodiment of the present disclosure includes a display panel 100, a source drive integrated circuit (hereinafter referred to as an “IC”) 510, a flexible film 520, a circuit board 530, and a timing controller 540.

The display panel 100 can include the first substrate 100a and the second substrate 100b facing each other. The second substrate 100b can be an encapsulation substrate. The first substrate 100a can be a plastic film, a glass substrate of a silicon wafer substrate formed by using a semiconductor process. The second substrate 100b can be a plastic film, a glass substrate, or an encapsulation film. The first substrate 100a and the second substrate 100b can be made of a transparent material.

The display panel 100 can be divided into a display area DA in which pixels are formed to display an image and a non-display area NDA in which an image is not displayed. As an example, the non display area NDA may partially or fully surround the display area DA, without being limited thereto.

The display panel 100 may include a plurality of signal lines disposed on the substrate. For example, first signal lines SL1, second signal lines SL2, and pixels can be provided in the display area DA, and a pad area PA in which pads are disposed and at least one gate driver 505 can be provided in the non-display area NDA.

The first signal lines SL1 can extend in a first direction, for example a Y axis direction (e.g., a column direction), and can cross the second signal lines SL2 in the display area DA. The second signal lines SL2 can extend in a second direction, for example an X axis direction (e.g., a row direction) in the display area DA, for example, in a direction intersecting the Y axis direction. The pixels are provided in an area in which the first signal line SL1 is provided or an area in which the first signal line SL1 and the second signal line SL2 intersect, and emit predetermined light to display an image.

The display driving circuit can include a source driver IC 510. The source drive IC 510 receives digital video data and a source control signal from the timing controller 540. The source drive IC 510 converts digital video data into analog data voltages according to a source control signal and supplies the converted analog data voltages corresponding to image (or video) signals to the data lines. When the source drive IC 510 is manufactured as a driving chip, the source drive IC 510 can be mounted on the flexible film 520 in a chip on film (COF) or chip on plastic (COP) manner, or implemented by a chip-on-glass (COG) method or a tape carrier package (TCP) method to be connected to the display panel 100, without being limited thereto.

Wirings connecting pads and the source drive IC 510 and wirings connecting pads and wirings of the circuit board 530 can be formed in the flexible film 520. The flexible film 520 is attached onto the pads using an anisotropic conducting film, and thus the wirings of the pads and the flexible film 520 can be connected to each other.

The circuit board 530 can be attached to the flexible films 520. A plurality of circuits implemented with driving chips can be mounted on the circuit board 530. For example, the timing controller 540 can be mounted on the circuit board 530. The circuit board 530 can be a printed circuit board or a flexible printed circuit board.

The timing controller 540 receives digital video data and a timing signal from an external system board. The timing controller 540 generates a gate control signal for controlling the operation timing of the gate driver 505 and a source control signal for controlling the source drive ICs 510, based on the timing signal. The timing controller 540 supplies the gate control signal to the gate driver 505, and supplies the source control signal to the source drive ICs 510.

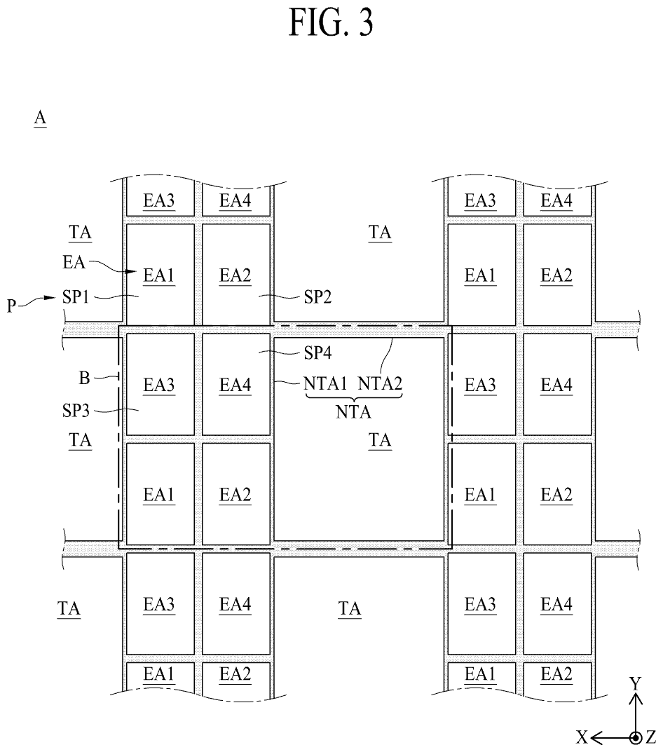

FIG. 3 is a plan view of a transparent display device according to an embodiment of the present disclosure. In this case, FIG. 3 is an enlarged view of an area A of FIG. 2.

Referring to FIG. 3, the display area DA includes a transmissive area TA and a non-transmissive area NTA. The transmissive area TA is an area that passes most of the light incident from the outside, and the non-transmissive area NTA is an area that does not transmit most of the light incident from the outside. For example, the transmissive area TA can be an area having a light transmittance greater than a %, and the non-transmissive area NTA can be an area having a light transmittance less than B %. In this case, a is a value greater than B. The transparent display panel 100 can see an object or a background positioned on the back of the transparent display panel 100 due to the transmissive areas TA.

The first non-transmissive area NTA1, the second non-transmissive area NTA2, and the pixel P can be provided in the non-transmissive area NTA.

The first non-transmissive area NTA1 can extend in a first direction (for example, a Y axis direction) in the display area DA and can be disposed to overlap at least a portion of the light emitting areas EA1, EA2, EA3, and EA4. In the transparent display panel 100, a plurality of first non-transmissive areas NTA1 are disposed to be spaced apart from each other, and a transmissive area TA can be provided between two adjacent first non-transmissive areas NTA1. In the first non-transmissive area NTA1, first signal lines SL1 extending in a first direction (for example, a Y axis direction) can be disposed to be spaced apart from each other.

The first signal lines SL1 can include at least one of a common power line, a reference line, data lines, and pixel power lines.

The pixel power line can supply a first power to the driving transistor T of each of the sub pixels SP1, SP2, SP3, and SP4 provided in the display area DA. The common power line can supply a second power to a cathode electrode of the sub pixels SP1, SP2, SP3, and SP4 provided in the display area DA. In this case, the second power can be a common power source supplied in common to the sub pixels SP1, SP2, SP3, and SP4.

The reference line can supply an initialization voltage (or a reference voltage) to the driving transistor T of each of the sub pixels SP1, SP2, SP3, and SP4 provided in the display area DA. Each of the data lines can supply a data voltage to the sub pixels SP1, SP2, SP3, and SP4.

The transparent display panel 100 according to an embodiment of the present disclosure includes a pixel P between adjacent transmissive areas TA, and the pixel P can include light emitting areas EA1, EA2, EA3, and EA4 in which a light emitting element is disposed to emit light. Since the transparent display panel 100 has a small area of the non-transmissive area NTA, the circuit element can be disposed to overlap the light emitting areas EA1, EA2, EA3, and EA4.

The second non-transmissive area NTA2 can extend in a second direction (for example, an X axis direction) in the display area DA and can be disposed to overlap at least a portion of the light emitting areas EA1, EA2, EA3, and EA4. In the transparent display panel 100, a plurality of second non-transmissive areas NTA2 are disposed to be spaced apart from each other, and a transmissive area TA can be provided between two adjacent second non-transmissive areas NTA2. A second signal line SL2 can be disposed in the second non-transmissive area NTA2.

The second signal line SL2 can extend in a second direction (for example, an X axis direction), and can include, for example, a gate line. The gate line can supply gate signals to the sub pixels SP1, SP2, SP3, and SP4 of the pixel P.

Each of the pixels P can include a first sub pixel SP1, a second sub pixel SP2, a third sub pixel SP3, and a fourth sub pixel SP4, as shown in FIG. 3. The first sub pixel SP1 can include a first light emitting area EA1 that emits first color light, and the second sub pixel SP2 can include a second light emitting area EA2 that emits second color light. The third sub pixel SP3 can include a third light emitting area EA3 that emits third color light, and the fourth sub pixel SP4 can include a fourth light emitting area EA4 that emits fourth color light.

For example, the first to fourth light emitting areas EA1, EA2, EA3, and EA4 can all emit light of different colors. For example, the first light emitting area EA1 can emit blue light, and the second light emitting area EA2 can emit red light. The third light emitting area EA3 can emit green light, and the fourth light emitting area EA4 can emit white light. However, the present disclosure is not limited thereto. Further, the arrangement order of each of the sub pixels SP1, SP2, SP3, and SP4 can be variously changed.

For example, the plurality of sub pixels SPX may include red, green, and blue sub-pixels, in which the red, green, and blue sub-pixels may be disposed in a repeated manner. Alternatively, the plurality of sub pixels SPX may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

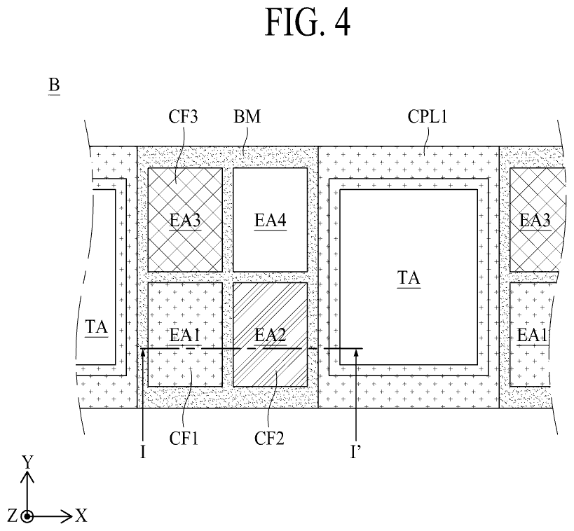

FIG. 4 is a plan view of a transparent display device according to an embodiment of the present disclosure. In this case, FIG. 4 is an enlarged view of area B of FIG. 3.

Referring to FIG. 4, the transparent display device according to an embodiment of the present disclosure can include the transmissive area TA and the first light emitting area EA1, the second light emitting area EA2, the third light emitting area EA3, and the fourth light emitting area EA4 provided on one side of the transmissive area TA, for example, on the left side.

Color filters CF1, CF2, and CF3 can be formed to correspond to the first light emitting area EA1, the second light emitting area EA2, and the third light emitting area EA3, respectively. For example, a first color filter CF1 for transmitting blue (B) light can be formed in the first light emitting area EA1, a second color filter CF2 for transmitting red R light can be formed in the second light emitting area EA2, and a third color filter CF3 for transmitting green G light can be formed in the third light emitting area EA3.

Accordingly, the light emitted from the first light emitting area EA1 can pass through the first color filter CF1 to display blue B, the light emitted from the second light emitting area EA2 can pass through the second color filter CF2 to display red R, and the light emitted from the third light emitting area EA3 can pass through the third color filter CF3 to display green G.

Meanwhile, a separate color filter may not be provided in the fourth light emitting area EA4. Accordingly, light emitted from the fourth light emitting area EA4 can display white W.

A black matrix BM for partitioning the first color filter CF1 to the third color filter CF3 can be formed around each of the first to fourth light emitting areas EA1 to EA4. The black matrix BM can be formed to overlap at least a portion of the first to fourth light emitting areas EA1 to EA4, but is not limited thereto.

Meanwhile, the black matrix BM may not be provided on one side of the fourth light emitting area EA4 displaying white W, for example, one side between the fourth light emitting area EA4 and the transmission area TA. Since the black matrix BM is not provided between the fourth light emitting area EA4 and the transmission area TA, an additional margin for preventing light leakage can be secured.

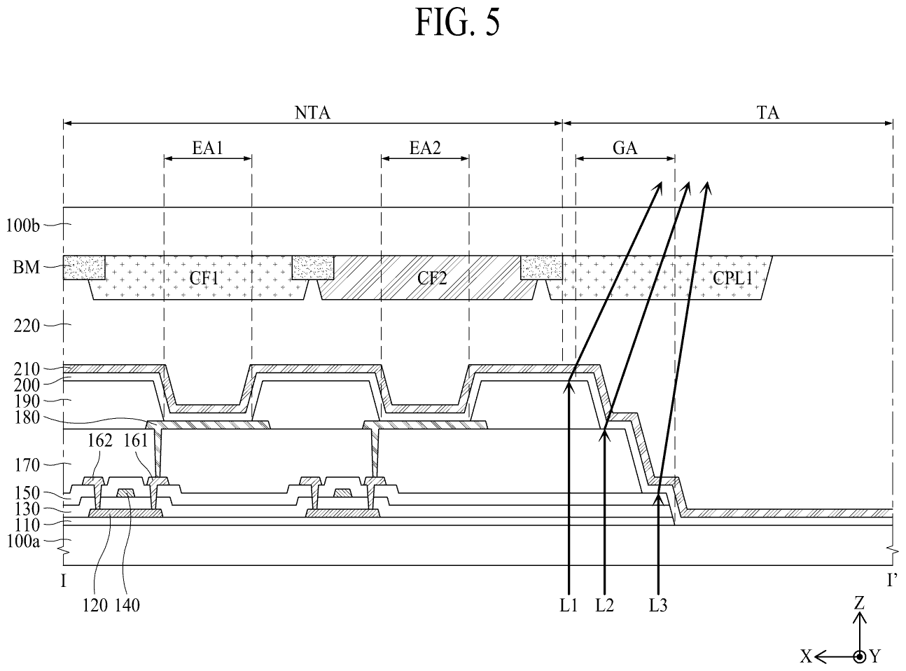

According to an embodiment of the present disclosure, the first color compensation layer CPL1 can be provided to surround the transmission area TA. Specifically, the first color compensation layer CPL1 can be provided to surround the transmission area TA and can overlap at least a portion of the transmission area TA. By forming in this way, the problem that the light introduced from the lower surface of the first substrate (see 100a in FIG. 1) of the transparent display device according to present embodiment becomes yellow and the problem of lowering the user's vision due to the blurred back of the transparent display device as it passes through the transmission area TA can be minimized. In this regard, it will be described in more detail with reference to FIG. 5 below.

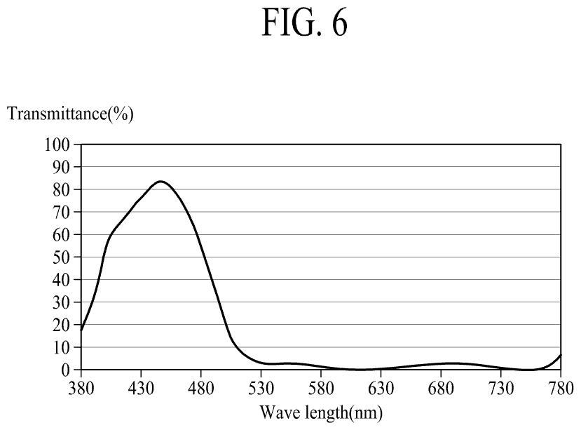

The first color compensation layer CPL1 can be formed using, for example, the same material as the first color filter CF1, but is not limited thereto. The light transmittance according to the wavelength of the first color compensation layer CPL1 will be described in more detail with reference to FIG. 6 below.

FIG. 5 is a cross-sectional view of a transparent display device according to an embodiment of the present disclosure. In this case, FIG. 5 corresponds to a cross-sectional view along line I-I′ of FIG. 4, and relates to a first light emitting area EA1, a second light emitting area EA2, and a transmission area TA.

Referring to FIG. 5, the transparent display device according to an embodiment of the present disclosure can include a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a black matrix BM, a first color filter CF1, a second color filter CF2, a first color compensation layer CPL1, and a second substrate 100b.

The first substrate 100a can be made of glass or plastic. Particularly, the first substrate 100a can be made of transparent plastic having flexible characteristics, for example, polyimide. When the polyimide is used as the first substrate 100a, considering that a high temperature deposition process is performed on the first substrate 100a, heat resistant polyimide capable of withstanding high temperature can be used.

The buffer layer 110 can be formed on the first substrate 100a. The buffer layer 110 can protect the active layer 120 by blocking air and moisture. The buffer layer 110 can be made of an inorganic insulating material such as silicon oxide, silicon nitride, or metal oxide, for example, the buffer layer 110 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but is not limited thereto and can be made of an organic insulating material. However, the buffer layer 110 may be excluded in accordance with the structure or properties of the display device.

The buffer layer 110 can be formed on the entire surface of the first substrate 100a, but is not limited thereto and can be formed to cover only a partial area of the transmissive area TA. For example, one end of the buffer layer 110, for example, a right end, can be provided in the transmissive area TA, and can be provided in the step area GA. For example, in the transmissive area TA, the buffer layer 110 is only disposed in the step area GA, but is not disposed in other regions excluding the step area GA.

The active layer 120 can be formed on the buffer layer 110. The active layer 120 can include any one of a semiconductor material, for example, amorphous silicon, polycrystalline silicon, and oxide semiconductor material, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The active layer 120 includes a channel portion that overlaps the gate electrode 140 to maintain semiconductor characteristics without being conductive in the conductive process, and a first connection portion provided on one side of the channel portion, for example, on the left side, and a second connection provided on another side, for example, on the right side, of the channel portion, and provided with conductive characteristics by the conductive process. In this case, the conductive process can be, for example, a process of performing plasma treatment on a semiconductor material using the gate electrode 140 as a mask, but is not limited thereto. The first connection portion and the second connection portion by the conductive process have excellent conductive characteristics and can serve as an electrode or a wiring.

The gate insulating layer 130 can be formed on the active layer 120. The gate insulating layer 130 can be formed on the entire surface of the first substrate 100a, but the present disclosure is not limited thereto, and a partial region of the gate insulating layer 130 can be patterned so that one end and another end of the gate insulating layer 130 correspond to one end and another end of the gate electrode 140, respectively.

The gate insulating layer 130 can be formed on the entire surface of the first substrate 100a, but is not limited thereto and can be formed to cover only a partial area of the transmissive area TA. For example, one end of the gate insulating layer 130, for example, a right end can be provided in the transmissive area TA, and can be provided in the step area GA. For example, in the transmissive area TA, the gate insulating layer 130 is only disposed in the step area GA, but is not disposed in other regions excluding the step area GA. In this case, one end of the gate insulating layer 130 can correspond to, for example, one end of the buffer layer 110, but is not limited thereto. For example, as shown in FIG. 5, one end of the gate insulating layer 130 overlaps with one end of the buffer layer 110 in the step area GA of the transmissive area TA, but the present disclosure is not limited thereto.

The gate insulating layer 130 can include a silicon nitride film (SiNx) or a silicon oxide film (SiOx), for example, the gate insulating layer 130 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but is not limited thereto. The gate insulating layer 130 can be formed of a single layer or a plurality of layers including an inorganic insulating material and/or an organic insulating material.

The gate electrode 140 can be formed on the gate insulating layer 130. The gate electrode 140 can include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 140 can have a structure including one metal layer or a multilayer structure including at least two metal layers each having different physical properties, but not limited thereto.

The interlayer insulating layer 150 can be formed on the gate electrode 140. The interlayer insulating layer 150 insulates between the gate electrode 140 and the source electrode 161 and further insulates between the gate electrode 140 and the drain electrode 162. The interlayer insulating layer 150 can be formed of a single layer or a plurality of layers including an inorganic insulating material and/or an organic insulating material. For example, the interlayer insulating layer 150 may be configured as a single layer or multilayer made of silicon nitride (SiNx) or silicon oxide (SiOx). For example, the interlayer insulating layer 150 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

A contact hole can be formed in the interlayer insulating layer 150. Accordingly, one side of the active layer 120, for example, a part of the right side, can be exposed by one contact hole, and further, another side, for example, a part of the left side, of the active layer 120 can be exposed by the other contact hole.

The interlayer insulating layer 150 can be formed on the entire surface of the first substrate 100a, but is not limited thereto and can be formed to cover only a partial area of the transmissive area TA. For example, one end of the interlayer insulating layer 150, for example, a right end can be provided in the transmissive area TA, and can be provided in the step area GA. For example, in the transmissive area TA, the interlayer insulating layer 150 is only disposed in the step area GA, but is not disposed in other regions excluding the step area GA. In this case, one end of the interlayer insulating layer 150 can correspond to, for example, one end of the buffer layer 110 and one end of the gate insulating layer 130, but is not limited thereto. For example, as shown in FIG. 5, one end of the interlayer insulating layer 150 overlaps with one end of the gate insulating layer 130 and one end of the buffer layer 110 in the step area GA of the transmissive area TA, but the present disclosure is not limited thereto.

The source electrode 161 and the drain electrode 162 can be disposed on the interlayer insulating layer 150. The source electrode 161 can be electrically connected to one side of the active layer 120 by a contact hole, and the drain electrode 162 can be electrically connected to another side of the active layer 120 by a contact hole.

The source electrode 161 and the drain electrode 162 can be formed of the same material as the gate electrode 140, but are not limited thereto, for example, each of the source electrode 161 and the drain electrode 162 may include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). Each of the source electrode 161 and the drain electrode 162 may have a structure including one metal layer or a multilayer structure including at least two metal layers each having different physical properties, but not limited thereto. Meanwhile, each of the source electrode 161 and the drain electrode 162 can be formed of a material according to knowledge in the art.

The planarization layer 170 can be formed on the interlayer insulating layer 150, the source electrode 161, and the drain electrode 162. The planarization layer 170 can be formed on the source electrode 161 and the drain electrode 162 to planarize an upper surface of the planarization layer 170.

A contact hole is provided in the planarization layer 170, and a part of the upper surface of the source electrode 161 can be exposed by the contact hole. However, in some cases, a part of the upper surface of the drain electrode 162 can be exposed by the contact hole, and the present disclosure is not limited thereto.

The planarization layer 170 can be formed of an organic insulating material. For example, the planarization layer 170 can be formed of an organic insulating material such as an acrylic resin, an epoxy resin, a phenolic resin, a polyamide resin, or a polyimide resin.

The planarization layer 170 can be formed up to a partial area of the transmissive area TA. For example, one end, for example, a right end of the planarization layer 170 can be provided in the transmissive area TA, and can be provided in the step area GA. For example, as shown in FIG. 5, one end of the planarization layer 170 partially overlaps with, for example, one end of the buffer layer 110, the gate insulating layer 130, and the interlayer insulating layer 150 in the step area GA of the transmissive area TA, but the present disclosure is not limited thereto.

One end of the planarization layer 170 may not coincide with, for example, one end of the buffer layer 110, the gate insulating layer 130, and the interlayer insulating layer 150. By forming in this way, a portion of the upper surface of the interlayer insulating layer 150 can be exposed from the planarization layer 170.

The first electrode 180 can be formed on the planarization layer 170 and can be electrically connected to the source electrode 161 through a contact hole provided in the planarization layer 170. The first electrode 180 can function as an anode electrode. The first electrode 180 can be patterned to correspond to the first sub pixel SP1 and the second sub pixel SP2.

The bank 190 can be formed on the first electrode 180. In this case, a partial region of the upper surface of the first electrode 180 exposed without being covered by the bank 190 becomes a light emitting area. The bank 190 can be disposed at a boundary between the plurality of subpixels SPX and suppress a color mixture of light beams from the plurality of subpixels SPX. The bank 190 can include an inorganic insulating material, such as silicon nitride (SiNx) or silicon oxide (SiOx). The bank 190 can be formed of an organic layer such as an acrylic resin, an epoxy resin, a phenolic resin, a polyamide resin, a polyimide resin, or the like. For example, the bank 190 can be formed of black resin. However, the present disclosure is not limited thereto.

The bank 190 can be formed up to a partial area of the transmissive area TA. For example, one end of the bank 190, for example, a right end, can be provided in the transmissive area TA, and can be provided in the step area GA. For example, as shown in FIG. 5, one end of the bank 190 partially overlaps with, one end of the planarization layer 170 in the step area GA of the transmissive area TA, but the present disclosure is not limited thereto. One end of the bank 190 may not coincide with one end of the planarization layer 170, for example. By forming in this way, a part of the upper surface of the planarization layer 170 can be exposed from the bank 190.

According to an embodiment of the present disclosure, a step area GA can be formed in a boundary area between the non-transmissive area NTA and the transmissive area TA. In the non-transmissive area NTA, a plurality of insulating layers, for example, the buffer layer 110, the gate insulating layer 130, the interlayer insulating layer 150, the planarization layer 170, and the bank 190 are formed, whereas a plurality of insulating layers are not formed in the transmissive area TA, and thus a step area having a predetermined thickness is formed between the non-transmissive area NTA and the transmissive area TA, and in the present disclosure, it can be defined as the step area GA. Alternatively, in FIG. 5, the step area GA is shown as a portion of the transmissive area TA, however, the present disclosure is not limited thereto, the step area GA may be a separate area between the non transmissive area NTA and the transmissive area TA.

The light emitting layer 200 can be formed on the first electrode 180. The light emitting layer 200 can be formed of, for example, a white emission layer connected to all pixels. When the light emitting layer 200 is formed of a white emission layer, the light emitting layer 200 can include, for example, a first stack including a blue emission layer, a second stack including a yellow green emission layer, and a charge generation layer provided between the first stack and the second stack, and the light emitting layer 200 of another embodiment can include, for example, a first stack including a blue emission layer, a second stack including a yellow green emission layer, for example, a third stack including a blue emission layer, a first charge generation layer provided between the first stack and the second stack, and a second charge generation layer provided between the second stack and the third stack, but is not limited thereto.

The light emitting layer 200 can be formed over the entire surface of the first light emitting area EA1, the second light emitting area EA2, and the transmissive area TA. However, the present disclosure is not limited thereto, and the light emitting layer 200 can be partially patterned and may not be provided in the transmissive area TA. Alternatively, the light emitting layer 200 may be partially patterned and may not be provided in other areas of the transmissive area TA excluding step area GA.

The light emitting layer 200 can be provided to cover an upper surface and one side surface, for example, a right side surface, of the bank 190 provided outside the second light emitting area EA2 in the step area GA, and can be provided to cover an upper surface and one side surface, for example, a right side surface, of the planarization layer 170. Furthermore, the light emitting layer 200 can be provided to cover one side surface, for example, a right side surface, of the buffer layer 110, the gate insulating layer 130, and can cover a part of the upper surface of the interlayer insulating layer 150. However, the present disclosure is not limited thereto.

The second electrode 210 can be formed on the light emitting layer 200. The second electrode 210 can function as a cathode. The second electrode 210 can be formed on, for example, the bank 190 and the light emitting layer 200. Accordingly, the second electrode 210 can be formed over the entire surfaces of the first light emitting area EA1, the second light emitting area EA2, and the transmissive area TA. However, the present disclosure is not limited thereto, and the second electrode 210 can be partially patterned and may not be provided in the transmissive area TA.

The encapsulation layer 220 can be formed on the second electrode 210. The encapsulation layer 220 can be formed on the entire surface of the first substrate 100a. Thus, it can be formed on the entire surfaces of the first sub pixel SP1, the second sub pixel SP2, and the first transmission area TA1. The encapsulation layer 220 can include acrylic resin, epoxy resin, polyimide, polyethylene (PE), or silicon oxycarbon (SiOC).

The encapsulation layer 220 can include a first encapsulation layer including an inorganic material, a second encapsulation layer including an organic material, and a third encapsulation layer including an inorganic material. For example, the encapsulation layer 220 may have a multi-insulating film structure in which organic films and inorganic films are stacked alternately. The inorganic film can block permeation of moisture or oxygen. The organic film can planarize a surface of the inorganic film. When the organic film and the inorganic film are stacked in multiple layers, a movement path of moisture or oxygen can be longer than that of a single layer, thereby effectively blocking the permeation of moisture and oxygen affecting the light emitting layer 200. For example, the encapsulation layer 220 includes a first inorganic encapsulation layer, a second organic encapsulation layer, and a third inorganic encapsulation layer stacked sequentially.

The first inorganic encapsulation layer, and the third inorganic encapsulation layer can serve to block the penetration of moisture or oxygen. The first inorganic encapsulation layer and the third inorganic encapsulation layer can be made of an inorganic material, for example, an inorganic material such as silicon nitride (SiNx), silicon oxide (SiOx), or aluminum oxide (AlOx). However, the present disclosure is not limited thereto.

The second organic encapsulation layer can be made of an organic material, and for example, epoxy polymer, acrylic polymer, or the like may be used. However, the present disclosure is not limited thereto.

Meanwhile, the encapsulation layer 220 is not limited to three layers, for example, n layers alternately stacked between inorganic encapsulation layer and organic encapsulation layer (where n is an integer greater than 3) can be included.

The first color filter CF1 and the second color filter CF2 can be formed on the encapsulation layer 220. Specifically, the first color filter CF1 can be provided on the encapsulation layer 220 and can correspond to the first light emitting area EA1. Further, the second color filter CF2 can be provided on the encapsulation layer 220 and can correspond to the second light emitting area EA2.

The first color filter CF1 and the second color filter CF2 can transmit any one of red R, green G, and blue B, and the first color filter CF1 and the second color filter CF2 can transmit light having different color. For example, the first color filter CF1 can transmit the blue (B) light, and the second color filter CF2 can transmit the red R light. Therefore, as described in FIG. 4, the light emitted from the first light emitting area EA1 can display blue B through the first color filter CF1, and the light emitted from the second light emitting area EA2 can display red R through the second color filter CF2.

According to an embodiment of the present disclosure, the first color compensation layer CPL1 can be formed on the encapsulation layer 220. In this case, the first color compensation layer CPL1 can be formed on the same layer as the first color filter CF1 and the second color filter CF2.

The first color compensation layer CPL1 can compensate for the color of light introduced from the lower surface of the first substrate 100a and passing through the insulating layer provided in the step area GA and can be exported to the second substrate 100b. In this case, the first color compensation layer CPL1 can have, for example, a complementary color relationship with a plurality of insulating layers provided in the step area GA. However, the present disclosure is not limited thereto.

Conventionally, the light passing through the transmissive area TA can be yellowish or the light passing through the transmissive area TA can be diffracted by a plurality of insulating layers provided in the step area GA, so that an object on the rear surface of the transparent display device can be visually recognized as blurred. According to an embodiment of the present disclosure, since the first color compensation layer CPL1 is formed in the area overlapping the step area GA to compensate for the colors of the light passing through the step area GA, for example, the first light L1, the second light L2, and the third light L3, it is possible to minimize or mitigate the phenomenon that the light passing through the step area GA becomes yellowish.

Furthermore, the first color compensation layer CPL1 is formed in the area overlapping the step area GA to reduce diffraction of the light passing through the step area GA, thereby improving the phenomenon in which the image of an object placed behind the rear surface of the transparent display device appears blurred, and through this, the user's visual sense can be improved.

The first color compensation layer CPL1 can be formed to overlap the step area GA. Specifically, one end of the first color compensation layer CPL1, for example, a right end thereof can protrude from the non-transmissive area NTA to the transmissive area TA rather than a right end of the buffer layer 110, the gate insulating layer 130, and the interlayer insulating layer 150, respectively. For example, one end of the first color compensation layer CPL1, for example, a right end thereof may extend beyond right ends of the buffer layer 110, the gate insulating layer 130, and the interlayer insulating layer 150, and protrude to the transmissive area TA excluding step area GA. By forming in this way, even if the third light L3 introduced from the lower surface of the first substrate 100a is refracted while passing through any one of the buffer layer 110, the gate insulating layer 130, and the interlayer insulating layer 150, the first color compensation layer CPL1 can be reached.

In addition, the second light L2 introduced from the lower surface of the first substrate 100a can be refracted while passing through the planarization layer 170 to reach the first color compensation layer CPL1, and the first light L1 introduced from the lower surface of the first substrate 100a can be refracted while passing through the bank 190 to reach the first color compensation layer CPL1.

The black matrix BM can be formed on the encapsulation layer 220, the first color filter CF1, the second color filter CF2, and the first color compensation layer CPL1. Specifically, the black matrix BM can be formed between the first color filter CF1 and the second color filter CF2, or can be formed between the second color filter CF2 and the first color compensation layer CPL1.

The black matrix BM overlaps the bank 190 and prevents the light emitted from the first light emitting area EA1 and passing through the first color filter CF1 and the light emitted from the second light emitting area EA2 and passing through the second color filter CF2 from being mixed with each other.

The second substrate 100b can be formed on the black matrix BM. The second substrate 100b can be bonded to face the first substrate 100a. The second substrate 100b can be referred to as an opposite substrate.

The second substrate 100b can be made of glass or plastic. In particular, the second substrate 100b can be made of transparent plastic having flexible characteristics, for example, polyimide.

FIG. 6 is a graph showing the transmittance of a first color compensation layer provided in a transparent display device according to an embodiment of the present disclosure for each wavelength band.

Referring to FIG. 6, the first color compensation layer (see CPL1 in FIG. 5) can be provided such that the transmittance of light in a wavelength range being greater than or equal to 380 nm and less than 500 nm is greater than the transmittance of the light in a wavelength range being greater than or equal to 500 nm and less than 780 nm. Here, the transmittance for light in the wavelength range being greater than or equal to 380 nm and less than 500 nm is greater than or equal to 20%. In this case, the transmittance can be defined as a relative ratio of the intensity of light emitted from a material to the intensity of light introduced into the material. In the present disclosure, the transmittance can be, for example, a relative ratio of the intensity of light emitted from the first color compensation layer CPL1 to the intensity of light introduced into the first color compensation layer CPL1.

According to an embodiment of the present disclosure, the first color compensation layer (see CPL1 of FIG. 5) can be provided to have a transmittance of light in a wavelength range greater than or equal to 350 nm and less than 500 nm greater than that of light in a wavelength range greater than or equal to 500 nm and less than 780 nm, thereby compensation for the colors of the light passing through the step area (see GA of FIG. 5), for example, the first light L1, the second light L2, and the third light L3. Accordingly, a phenomenon in which the light passing through the step area (see GA of FIG. 5) can be yellowed can be minimized or mitigated, and further, diffraction of the light passing through the step area GA can be reduced, thereby improving a phenomenon in which the image of an object placed behind the rear surface of the transparent display device is blurred, thereby improving visibility of the user.

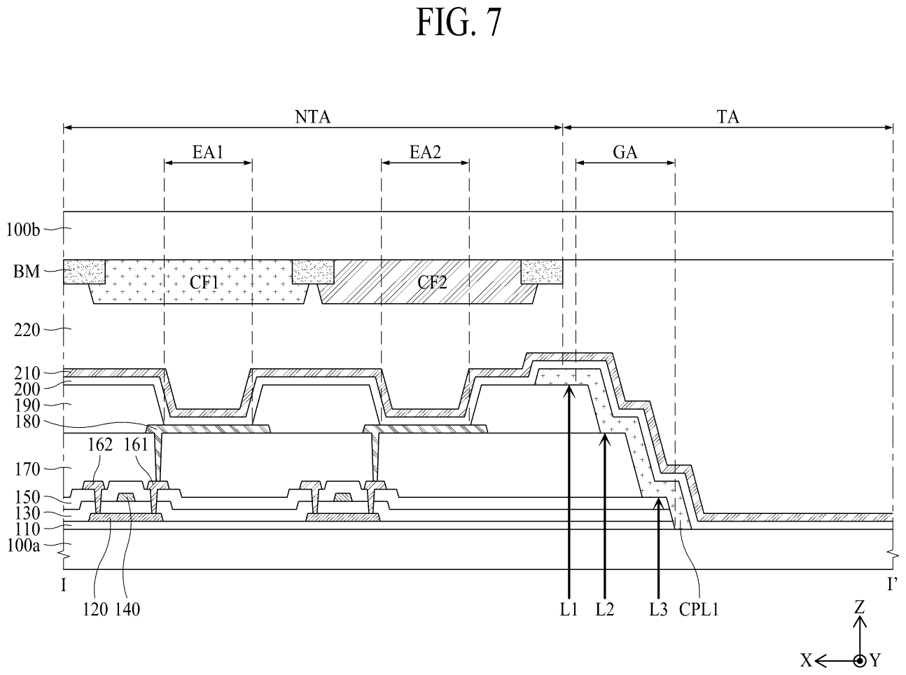

FIG. 7 is a cross sectional view of a transparent display device according to another embodiment of the present disclosure. In this case, FIG. 7 corresponds to a cross-sectional view along line I-I′ of FIG. 4. Meanwhile, an embodiment of FIG. 7 is the same as an embodiment of FIG. 5 except for the position of the first color compensation layer, and thus different configurations will be mainly described below.

Referring to FIG. 7, the transparent display device according to another embodiment of the present disclosure can include a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a black matrix BM, a first color filter CF1, a second color filter CF2, a first color compensation layer CPL1, and a second substrate 100b.

According to another embodiment of the present disclosure, the first color compensation layer CPL1 can be formed in an area overlapping the step area GA. However, unlike the embodiment of FIG. 5, the first color compensation layer CPL1 provided in the transparent display device of FIG. 7 is not formed on the same layer as the first color filter CF1 and the second color filter CF2.

The first color compensation layer CPL1 can be provided to cover top and side surfaces of a plurality of insulating layers formed in the step area GA. Specifically, the first color compensation layer CPL1 can be provided to cover one side surface, for example, a right side surface of the buffer layer 110, the gate insulating layer 130, the interlayer insulating layer 150, the planarization layer 170, and the bank 190, and the first color compensation layer CPL1 can be provided to cover a portion of the top surface of the bank 190 provided at the outermost portion of the second light emitting area EA2. The first color compensation layer CPL1 can be provided to cover a plurality of insulating layers in the step area GA, and thus, colors of the light passing through the step area GA, for example, the first light L1, the second light L2, and the third light L3 can be compensated. Accordingly, a problem in which the light passing through the step area GA is yellowish or the degree of diffraction of the light passing through the step area GA is reduced, thereby minimizing or mitigating a problem in which the rear surface of the transparent display device is visually recognized as being blurred, and thus, the user's visual sense can be improved.

Since the first color compensation layer CPL1 is provided to cover upper and side surfaces of a plurality of insulating layers formed in the step area GA, the first color compensation layer CPL1 can be provided at a lower position in the vertical direction Z than the first color filter CF1 and the second color filter CF2.

Since the first color compensation layer CPL1 is provided to be in contact with a portion of the upper surface of the first substrate 100a from the upper surface of the outermost bank 190, even if the light flowing into and passing through the step area GA is refracted, the first color compensation layer CPL1 can pass through.

According to another embodiment of the present disclosure, since the first color compensation layer CPL1 is formed on the first substrate 100a, even if a certain level of error occurs in the process of bonding the first substrate 100a and the second substrate 100b, all light flowing into the lower surface of the first substrate 100a is compensated for by the first color compensation layer CPL1. Accordingly, a problem in which the light passing through the step area GA is yellowish or the degree of diffraction of the light passing through the step area GA is reduced, thereby minimizing a problem in which the rear surface of the transparent display device is visually recognized as being blurred, and thus, the user's visual sense can be improved.

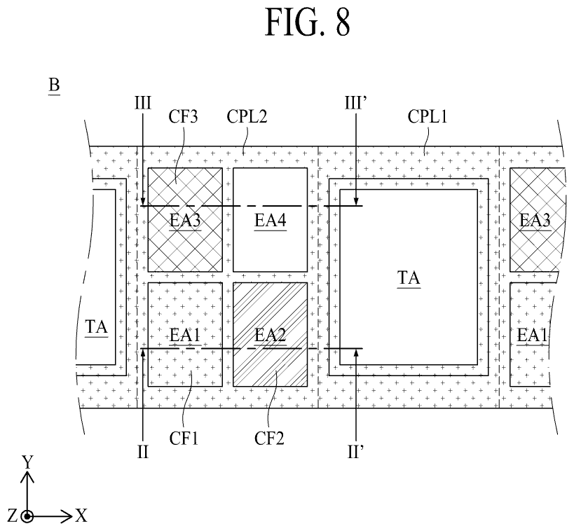

FIG. 8 is a plan view of a transparent display device according to another embodiment of the present disclosure. In this case, FIG. 8 is an enlarged view of area B of FIG. 3. Meanwhile, an embodiment of FIG. 8 is the same as an embodiment of FIG. 4 except for the configuration of the second color compensation layer, and thus different configurations will be mainly described below.

Referring to FIG. 8, the transparent display device according to another embodiment of the present disclosure can include the transmissive area TA and the first light emitting area EA1, the second light emitting area EA2, the third light emitting area EA3, and the fourth light emitting area EA4 provided on one side of the transmissive area TA, for example, on the left side of the transmissive area TA.

According to an embodiment of FIG. 8, while the black matrix (see BM of FIG. 4) is formed in the first to fourth light emitting areas EA1 to EA4 in an embodiment of FIG. 4, a second color compensation layer CPL2 for partitioning the first to third color filters CF1 to CF3 can be formed around each of the first to fourth light emitting areas EA1 to EA4. The second color compensation layer CPL2 can be formed to overlap at least a portion of the first to fourth light emitting areas EA1 to EA4, but is not limited thereto.

The second color compensation layer CPL2 can include the same material as the first color compensation layer CPL1. Further, the second color compensation layer CPL2 can be formed using the same material as the first color filter CF1, but is not limited thereto.

Furthermore, as described in FIG. 6, the second color compensation layer CPL2 can be provided such that the transmittance for light in a wavelength range greater than or equal to 380 nm and less than 500 nm is greater than that for light in a wavelength range greater than or equal to 500 nm and less than 780 nm, and the transmittance for light in a wavelength range greater than or equal to 380 nm and less than 500 nm is greater than or equal to 20%. However, it is not limited thereto.

Meanwhile, the second color compensation layer CPL2 may not be provided on one side of the fourth light emitting area EA4 displaying white W, for example, a side disposed between the fourth light emitting area EA4 and the transmission area TA, and on another side, for example, on the upper side of the fourth light emitting area EA4. Since the second color compensation layer CPL2 is not provided between the fourth light emitting area EA4 and the transmission area TA or on the upper side of the fourth light emitting area EA4, an additional margin for preventing light leakage can be secured.

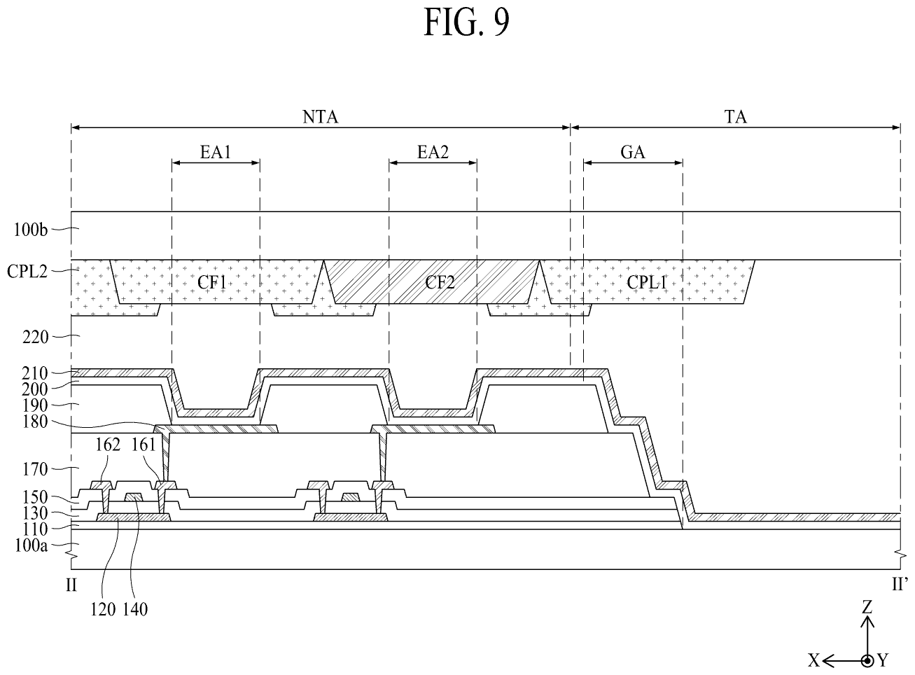

FIG. 9 is a cross sectional view of a transparent display device according to another embodiment of the present disclosure. In this case, FIG. 9 corresponds to the cross section II-II′ of FIG. 8. Meanwhile, an embodiment of FIG. 9 is the same as an embodiment of FIG. 5 except for the configuration of the second color compensation layer, and thus different configurations will be mainly described below.

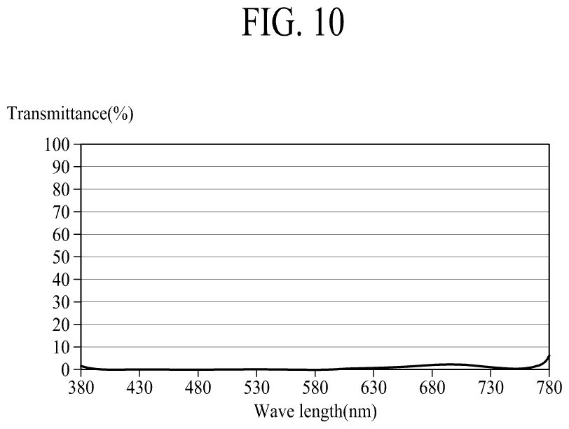

Furthermore, FIG. 10 is a graph showing transmittance for each wavelength band at a boundary of any one light emitting area provided in a transparent display device according to another embodiment of the present disclosure. In this case, FIG. 10 is a graph showing transmittance for each wavelength band when light passes through the second color compensation layer CPL2 and the second color filter CF2 that passes the red R in an embodiment of FIG. 9.

Referring to FIG. 9, the transparent display device according to another embodiment of the present disclosure can include a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a first color filter CF1, a second color filter, a first color compensation layer CPL1, a second color compensation layer CPL2, and a second substrate 100b. Unlike the embodiment of FIG. 5, an embodiment of FIG. 9 can include a second color compensation layer CPL2 instead of the black matrix (see BM of FIG. 5).

The second color compensation layer CPL2 can be formed in the same process as the process of forming the first color compensation layer CPL1, or can be formed in the same process as the process of forming the first color filter CF1. According to another configuration of the present disclosure, by using the second color compensation layer CPL2 to partition the first color filter CF1 and the second color filter CF2, mixing of the first color filter CF1 and the second color filter CF2 can be prevented in one process without an additional mask.

According to another embodiment of the present disclosure, the second color compensation layer CPL2 can be formed on the encapsulation layer 220, and can be formed under the first color filter CF1, the second color filter CF2, and the first color compensation layer CPL1. Specifically, the second color compensation layer CPL2 can be provided between the first color filter CF1 and the second color filter CF2, and can be provided between the second color filter CF2 and the first color compensation layer CPL1.

The second color compensation layer CPL2 can be provided to cover one side of the first color filter CF1, for example, the right and another side, for example, the left side. In addition, the second color compensation layer CPL2 can be provided to cover one side of the second color filter CF2, for example, the right and another side, for example, the left side. According to another embodiment of the present disclosure, the second color compensation layer CPL2 is provided to overlap a portion of the second color filter CF2 that transmits the red R, so that even if the light emitted from the first light emitting area EA1 passes through the first color filter CF1 and proceeds to the second color filter CF2, color mixing can be prevented, and conversely, even if the light emitted from the second light emitting area EA2 passes through the second color filter CF2 and proceeds to the first color filter CF1, color mixing can be prevented.

Referring to FIG. 10, in the area where the second color compensation layer CPL2 and the second color filter CF2 overlap, it can be seen that the transmittance of light in the wavelength range greater than or equal to 380 nm and less than 780 nm is less than or equal to 5%. Accordingly, according to an embodiment of the present disclosure, by dividing the first color filter CF1 and the second color filter CF2 into the second color compensation layer CPL2, light emitted from the second light emitting area EA2 and passing through the second color filter CF2 can be prevented from being mixed by the adjacent first color filter CF1. Meanwhile, according to an exemplary embodiment of the present disclosure, by dividing the first color filter CF1 and the second color filter CF2 into the second color compensation layer CPL2, light emitted from the first light emitting area EA1 and passing through the first color filter CF1 can be prevented from being mixed by the adjacent second color filter CF2.

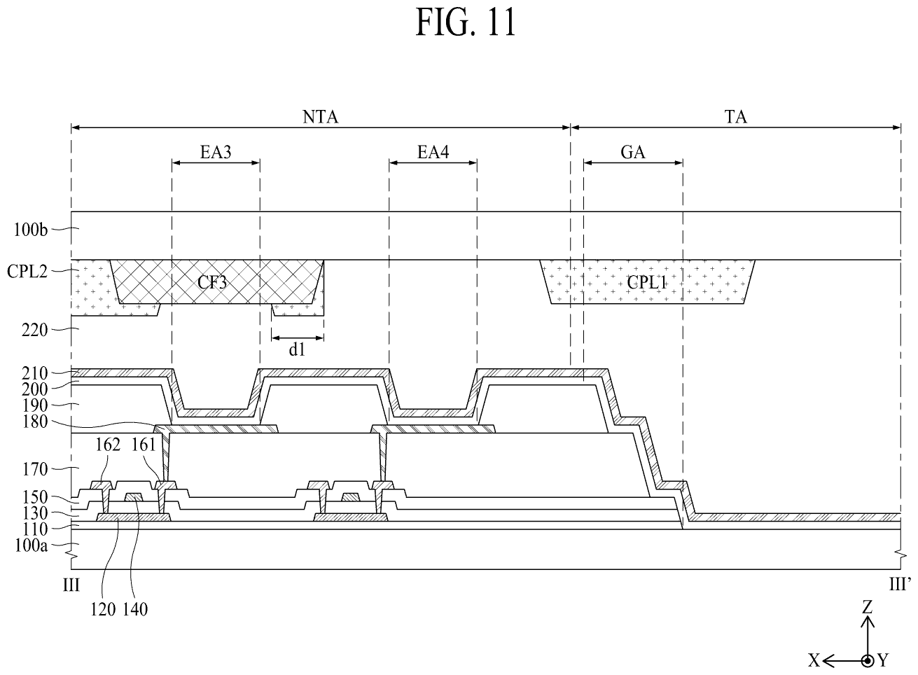

FIG. 11 is a cross-sectional view of a transparent display device according to another embodiment of the present disclosure. In this case, FIG. 11 corresponds to the cross section III-III′ of FIG. 8, and relates to the third light emitting area EA3, the fourth light emitting area EA4, and the transmission area TA. Meanwhile, an embodiment of FIG. 11 is the same as an embodiment of FIG. 9 except for the third light emitting area EA3 and the fourth light emitting area EA4, and thus different configurations will be mainly described below.

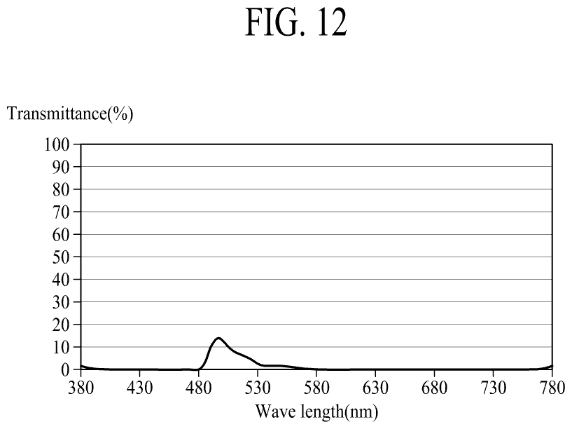

FIG. 12 is a graph showing transmittance for each wavelength band at the boundary of any one light emitting area provided in a transparent display device according to another embodiment of the present disclosure. In this case, FIG. 12 is a graph showing transmittance for each wavelength band when light passes through the second color compensation layer CPL2 and the third color filter CF3 that passes the green G in an embodiment of FIG. 11.

Referring to FIG. 11, a transparent display device according to another embodiment of the present disclosure can include a first substrate 100a, a buffer layer 110, an active layer 120, a gate insulating layer 130, a gate electrode 140, an interlayer insulating layer 150, a source electrode 161, a drain electrode 162, a planarization layer 170, a first electrode 180, a bank 190, a light emitting layer 200, a second electrode 210, an encapsulation layer 220, a third color filter CF3, a first color compensation layer CPL1, a second color compensation layer CPL2, and a second substrate 100b.

According to another embodiment of the present disclosure, the third color filter CF3 can be formed on the encapsulation layer 220 in the third light emitting area EA3. Specifically, the third color filter CF3 can correspond to the third light emitting area EA3.

On the other hand, a separate color filter may not be formed in the fourth light emitting area EA4. Accordingly, the light emitted from the fourth light emitting area EA4 can be emitted through the encapsulation layer 220 and the second substrate 100b to display white W.

The second color compensation layer CPL2 can be formed on the encapsulation layer 220 and can be formed under the third color filter CF3. Specifically, the second color compensation layer CPL2 can be provided to cover one side of the third color filter CF3, for example, the right side and another side, for example, the left side. According to another embodiment of the present disclosure, since the second color compensation layer CPL2 is provided to overlap a portion of the third color filter CF3 that transmits the green G, the light emitted from the third light emitting area EA3 is not transmitted through the third color filter CF3, and thus color mixing can be prevented from occurring in the fourth light emitting area EA4.

According to another embodiment of the present disclosure, the second color compensation layer CPL2 provided on one side, for example, the right side, of the third color filter CF3 can be provided to cover the upper surface and the side surface of the third color filter CF3. In this case, a length in which one side of the third color filter CF3 is covered by the second color compensation layer CPL2 can be defined as the first length d1.

The first length d1 can be formed to have a length that does not cause color mixing in the fourth light emitting area EA4, even if the light emitted from the third light emitting area EA3 is refracted while passing through the second electrode 210 or the encapsulation layer 220. In this case, the first length d1 varies depending on a technology level in the art, and although the third color filter CF3 has been described herein, the present disclosure is not limited thereto, and the first color filter (see CF1 of FIG. 9) and the second color filter (see CF2 of FIG. 9) shown in an embodiment of FIG. 9 can be applied in the same manner.

Meanwhile, it can be seen that in the area where the second color compensation layer CPL2 and the third color filter CF3 overlap, the light transmittance in the wavelength range greater than or equal to 380 nm and less than 780 nm is less than or equal to 15%, as shown in FIG. 12. Accordingly, according to an embodiment of the present disclosure, by dividing the third color filter CF3 into the second color compensation layer CPL2, light emitted from the third light emitting area EA3 and displayed by the adjacent fourth light emitting area EA4 can be prevented from being mixed by the light passing through the third color filter CF3.

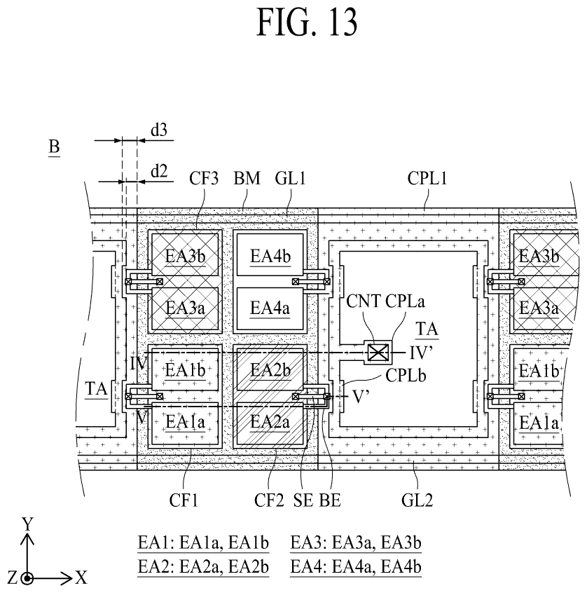

FIG. 13 is a plan view of a transparent display device according to another embodiment of the present disclosure. In this case, FIG. 13 is an enlarged view of area B of FIG. 3. Meanwhile, an embodiment of FIG. 13 is the same as an embodiment of FIG. 4 except for configurations of a gate line, a connection electrode, a contact portion, and each light emitting area, and thus different configurations will be mainly described below.

Referring to FIG. 13, the transparent display device according to an embodiment of the present disclosure can include the transmissive area TA and the first light emitting area EA1, the second light emitting area EA2, the third light emitting area EA3, and the fourth light emitting area EA4 provided on one side of the transmissive area TA, for example, on the left side. The first light emitting area EA1 can include a 1-1 light emitting area EA1a disposed at lower part, and a 1-2 light emitting area EA1b disposed at upper part. The second light emitting area EA2 can include a 2-1 light emitting area EA2a disposed at lower part, and a 2-2 light emitting area EA2b disposed at upper part. The third light emitting area EA3 can include a 3-1 light emitting area EA3a disposed at lower part, and a 3-2 light emitting area EA3b disposed at upper part. The fourth light emitting area EA4 can include a 4-1 light emitting area EA4a disposed at lower part, and a 4-2 light emitting area EA4b disposed at upper part.

A first gate line GL1 for supplying a gate signal to each of the third light emitting area EA3 and the fourth light emitting area EA4 can be formed on the third light emitting area EA3 and the fourth light emitting area EA4, and a second gate line GL2 for supplying a gate signal to the first light emitting area EA1 and the second light emitting area EA2 can be formed below the first light emitting area EA1 and the second light emitting area EA2.

According to another embodiment of the present disclosure, the first gate line GL1 and the second gate line GL2 can be provided to overlap the black matrix BM and the first color compensation layer CPL1.

As the first color compensation layer CPL1 overlaps the first gate line GL1 and the second gate line GL2, even if the light transmitted from the rear surface of the transparent display panel (refer to 100 in FIG. 2) is refracted or diffracted by a step formed in the first gate line GL1 or the second gate line GL2, a phenomenon in which the image of an object placed behind the rear surface of the transparent display panel (refer to 100 in FIG. 2) appears blurred can be minimized or eliminated.

The contact part CNT can be formed in a central portion of the transmissive area TA. The contact part CNT can extend from an adjacent light emitting area, for example, the second light emitting area EA2 and be positioned in the transmissive area TA. Meanwhile, the present disclosure is not limited thereto, and can extend from any one of another light emitting areas EA1, EA3, and EA4 and be positioned in the transmissive area TA. The contact part CNT can supply a signal of the common power line and can be electrically connected to the second electrode (see 210 in FIG. 5) in the transmissive area TA. By forming in this way, a voltage of the second electrode 210 (see FIG. 5) functioning as the common electrode of the transparent display panel 100 (see FIG. 2) can be prevented from decreasing. Therefore, it is possible to prevent uneven light emission in each light emitting region.

According to another embodiment of the present disclosure, a first color compensation layer pattern CPLa can be additionally formed to overlap the contact part CNT. The first color compensation layer pattern CPLa can include the same material as the first color compensation layer CPL1. By forming the first color compensation layer pattern CPLa in the region overlapping the contact part CNT, even if the light passing through the contact part CNT is diffracted, a phenomenon in which the image of an object placed behind the rear surface of the transparent display panel (see 100 in FIG. 2) appears blurred can be minimized or removed.

Color filters CF1, CF2, and CF3 can be formed to correspond to the first light emitting area EA1, the second light emitting area EA2, and the third light emitting area EA3, respectively. For example, a first color filter CF1 for transmitting blue B light can be formed in the first light emitting area EA1, a second color filter CF2 for transmitting red R light can be formed in the second light emitting area EA2, and a third color filter CF3 for transmitting green G light can be formed in the third light emitting area EA3. Meanwhile, a color filter can not be formed in the fourth light emitting area EA4.

Accordingly, the light emitted from the first light emitting area EA1 can pass through the first color filter CF1 to display blue B, the light emitted from the second light emitting area EA2 can pass through the second color filter CF2 to display red R, and the light emitted from the third light emitting area EA3 can pass through the third color filter CF3 to display green G.

Meanwhile, a separate color filter may not be provided in the fourth light emitting area EA4. Accordingly, light emitted from the fourth light emitting area EA4 can display white W.

A black matrix BM for partitioning the first color filter CF1 to the third color filter CF3 can be formed around each of the first to fourth light emitting areas EA1 to EA4. The black matrix BM can be formed to overlap at least a portion of the first to fourth light emitting areas EA1 to EA4, but is not limited thereto. Meanwhile, FIG. 13 illustrates only a state in which a black matrix BM is formed around the first to fourth light emitting areas EA1 to EA4, but the present disclosure is not limited thereto. A second color compensation layer (see CPL2 of FIG. 8) can be formed as in an embodiment of FIG. 8.

According to another embodiment of the present disclosure, the first to fourth light emitting areas EA1 to EA4 can include two light emitting areas each connected by a connection electrode BE. For example, the first light emitting area EA1 can include the 1-1 light emitting area EA1a and the 1-2 light emitting area EA1b connected by a connection electrode BE, and the second light emitting area EA2 can include the 2-1 light emitting area EA2a and the 2-2 light emitting area EA2b connected by a connection electrode BE, and the third light emitting area EA3 can include the 3-1 light emitting area EA3a and the 3-2 light emitting area EA3b connected by a connection electrode BE, and the fourth light emitting area EA4 can include the 4-1 light emitting area EA4a and the 4-2 light emitting area EA4b connected by a connection electrode BE. However, the present disclosure is not limited thereto.

The connection electrode BE can connect two light emitting areas to one driving transistor through a contact hole. Accordingly, the connection electrode BE connecting the 1-1 light emitting area EA1a and the 1-2 light emitting area EA1b is connected to one driving transistor through a contact hole, and the connection electrode BE connecting the 2-1 light emitting area EA2a and the 2-2 light emitting area EA2b is connected to another driving transistor through a contact hole, and the connection electrode BE connecting the 3-1 light emitting area EA3a and the 3-2 light emitting area EA3b is connected to another driving transistor through a contact hole, and the connection electrode BE connecting the 4-1 light emitting area EA4a and the 4-2 light emitting area EA4b is connected to another driving transistor through a contact hole.

By forming in this way, when a problem occurs in any one of the two light emitting areas, for example, when a dark spot is formed, any one of the two light emitting areas can be disconnected and only the other light emitting area can be used. For example, in the case of the first light emitting area EA1, when any one of the 1-1 light emitting area EA1a and the 1-2 light emitting area EA1b does not operate normally, the dark spot can occur. In this case, by blocking the connection electrode BE connected to any one of the 1-1 light emitting area EA1a and the 1-2 light emitting area EA1b, it is possible to prevent the dark spot from being formed by utilizing only the other light emitting area of the 1-1 light emitting area EA1a and the 1-2 light emitting area EA1b. For example, in the case of the second light emitting area EA2, when any one of the 2-1 light emitting area EA2a and the 2-2 light emitting area EA2b does not operate normally, the dark spot may occur. In this case, by blocking the connection electrode BE connected to any one of the 2-1 light emitting area EA2a and the 2-2 light emitting area EA2b, it is possible to prevent the dark spot from being formed by utilizing only the other light emitting area of the 2-1 light emitting area EA2a and the 2-2 light emitting area EA2b. For example, in the case of the third light emitting area EA3, when any one of the 3-1 light emitting area EA3a and the 3-2 light emitting area EA3b does not operate normally, the dark spot may occur. In this case, by blocking the connection electrode BE connected to any one of the 3-1 light emitting area EA3a and the 3-2 light emitting area EA3b, it is possible to prevent the dark spot from being formed by utilizing only the other light emitting area of the 3-1 light emitting area EA3a and the 3-2 light emitting area EA3b. For example, in the case of the first light emitting area EA4, when any one of the 4-1 light emitting area EA4a and the 4-2 light emitting area EA4b does not operate normally, the dark spot can occur. In this case, by blocking the connection electrode BE connected to any one of the 4-1 light emitting area EA4a and the 4-2 light emitting area EA4b, it is possible to prevent the dark spot from being formed by utilizing only the other light emitting area of the 4-1 light emitting area EA4a and the 4-2 light emitting area EA4b. However, the present disclosure is not limited thereto.

Meanwhile, while the connection electrode BE is formed in any one of the light emitting areas EA1 to EA4, a part of the step area (see GA in FIG. 5) can protrude in the horizontal direction (X).

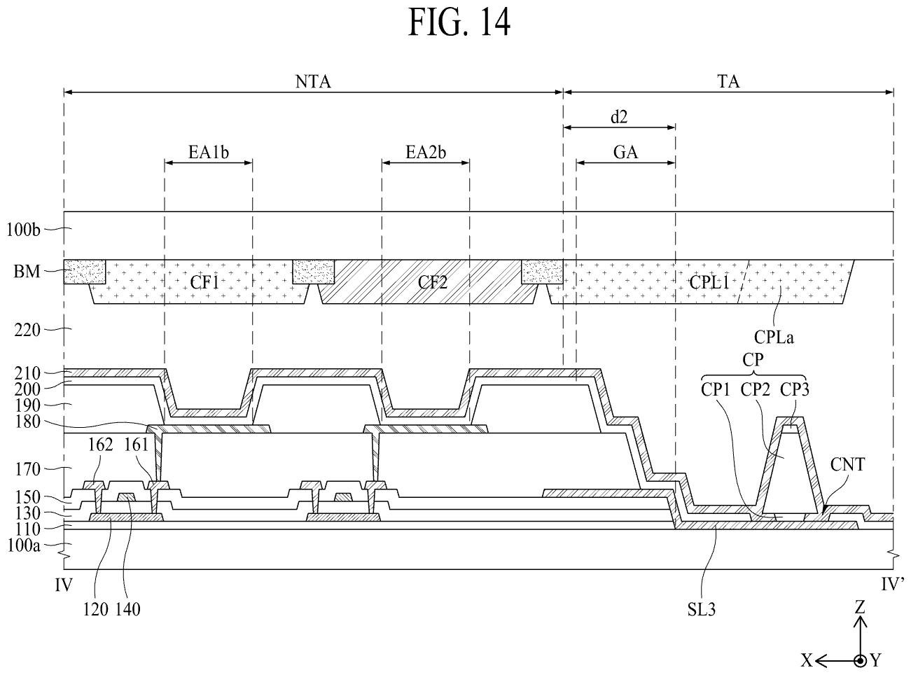

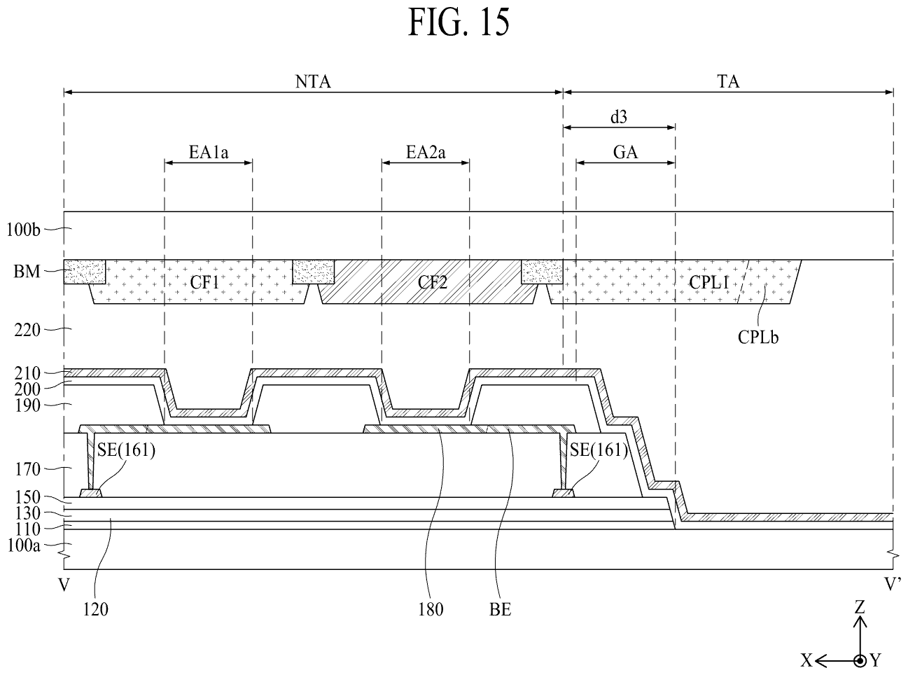

For example, referring to the third light emitting area EA3, the step area (see GA of FIG. 15) in the area where the connection electrode BE is formed can be formed to protrude in a direction of the transmission area TA compared to the step area (see GA of FIG. 14) in the area where the connection electrode BE is not formed. For example, in the area where the connection electrode BE is not formed, the step area (see GA of FIG. 14) is spaced apart from one end of the black matrix BM by a second distance d2, whereas in the area where the connection electrode BE is formed, the step area (see GA of FIG. 15) is spaced apart from one end of the black matrix BM by a third distance d3. In this case, the second distance d2 can be smaller than the third distance d3. In this case, the second distance d2 and the third distance d3 can be defined as the shortest distance from one end of the black matrix BM to one end of the step area (see GA of FIG. 14 and FIG. 15).

According to another embodiment of the present disclosure, a second color compensation layer pattern CPLb can be additionally formed in a partial region of the first color compensation layer CPL1 to cover the step area (see GA of FIG. 5) protruding from the region where the connection electrode BE is formed by a third distance d3. By forming in this way, the degree of refraction or diffraction of light incident from the rear surface of the transparent display device in the step area (see GA of FIG. 5) protruding from the region where the connection electrode BE is formed is reduced, so that a phenomenon in which the image of an object placed behind the rear surface of the transparent display device is blurred can be improved, and visibility of the user can be improved.

The second color compensation layer pattern CPLb can include the same material as the first color compensation layer CPL1. Meanwhile, the second color compensation layer pattern CPLb will be described in more detail with reference to FIG. 14.

FIG. 14 is a cross sectional view of a transparent display device according to another embodiment of the present disclosure. In this case, FIG. 14 corresponds to a cross-sectional view along line IV-IV′ of FIG. 13, and relates to a 1-2 th light emitting area EA1b, a 2-2 th light emitting area EA2b, and a transmission area TA. Meanwhile, an embodiment of FIG. 14 is the same as an embodiment of FIG. 5 except for configurations of the contact portion, the third signal line, and the first color compensation layer pattern, and thus different configurations will be mainly described below.

Referring to FIG. 14, the transparent display device according to another embodiment of the present disclosure can include a first substrate 100a, a buffer layer 110, an active layer 120, a gate insulating layer 130, a gate electrode 140, an interlayer insulating layer 150, a source electrode 161, a drain electrode 162, a third signal line SL3, a planarization layer 170, a voltage compensation pattern CP, a first electrode 180, a bank 190, a light emitting layer 200, a second electrode 210, an encapsulation layer 220, a black matrix BM, a first color filter CF1, a second color filter CF2, a first color compensation layer pattern CPLa, and a second substrate 100b.

According to another embodiment of the present disclosure, a third signal line SL3 extending from one side of the non-transmissive area NTA, for example, a right side of the non-transmissive area NTA to the transmissive area TA, can be formed over the upper surface of the interlayer insulating layer 150 and the upper surface of the first substrate 100a. The third signal line SL3 can receive power applied from the common power line. Meanwhile, in the present embodiment, only a state in which the third signal line SL3 is formed on the upper surface of the interlayer insulating layer 150 is illustrated, but the present disclosure is not limited thereto, and can be formed on any one of the insulating layers forming the step area GA.

In the transmission area TA, the third signal line SL3 is formed on the first substrate 100a. A voltage compensation pattern CP can be formed on the third signal line SL3. Since the voltage compensation pattern CP is formed on the third signal line SL3 in the transmission area TA, power applied from the common power line applied to the third signal line SL3 can be supplied to the second electrode 210.

The voltage compensation pattern CP includes a first pattern CP1, a second pattern CP2, and a third pattern CP3.

The first pattern CP1 is formed on the third signal line SL3. The first pattern CP1 can include an insulating material.

The second pattern CP2 is formed on the first pattern CP1. In this case, an area of a lower surface of the second pattern CP2 can be formed to be greater than an area of an upper surface of the first pattern CP1. The second pattern CP2 can be formed in the same process as the process of forming the planarization layer 170, but the present disclosure is not limited thereto.

By forming in this way, the contact part CNT can be formed by preventing the light emitting layer 200 from being formed in the region where the voltage compensation pattern CP is formed, and the second electrode 210 can be electrically connected to the third signal line SL3 exposed from the contact part CNT. In this case, power applied from the common power line through the third signal line SL3 can be supplied to the second electrode 210. Therefore, it is possible to prevent the voltage of the second electrode (see 210 of FIG. 5) functioning as a common electrode of the transparent display panel (see 100 of FIG. 2) from falling, and to prevent non-uniform light emission from occurring in each light emitting area.

The third pattern CP3 can be formed on the second pattern CP2. The third pattern CP3 can be formed in the same process as the process of forming the light emitting layer 200, but the present disclosure is not limited thereto.

According to another embodiment of the present disclosure, the first color compensation layer CPL1 can extend in a horizontal direction (X direction). Accordingly, the first color compensation layer pattern CPLa of the first color compensation layer CPL1 can overlap the third signal line SL3 formed on the first substrate 100a and the voltage compensation pattern CP formed on the third signal line SL3.

Since the first color compensation layer pattern CPLa overlaps both the third signal line SL3 and the voltage compensation pattern CP, even if the light transmitted from the rear surface of the transparent display panel (refer to 100 in FIG. 2) is refracted or diffracted by a step formed by the third signal line SL3 or the voltage compensation pattern CP, a phenomenon in which the image of an object placed behind the rear surface of the transparent display panel (refer to 100 in FIG. 2) appears blurred can be minimized or eliminated.

FIG. 15 is a cross-sectional view of a transparent display device according to another embodiment of the present disclosure. In this case, FIG. 15 corresponds to a cross-sectional view along line V-V′ of FIG. 13, and relates to a 1-1 light emitting area EA1a, a 2-1 light emitting area EA2a, and a transmission area TA. In this case, an embodiment of FIG. 15 is the same as an embodiment of FIG. 5 except for the first electrode, the connection electrode, and the second color compensation layer pattern, and thus different configurations will be mainly described below.

Referring to FIG. 15, the transparent display device according to another embodiment of the present disclosure can include a first substrate 100a, a buffer layer 110, a gate insulating layer 130, an interlayer insulating layer 150, a source electrode SE 161, a planarization layer 170, a first electrode 180, a connection electrode BE, a bank 190, a light emitting layer 200, a second electrode 210, an encapsulation layer 220, a black matrix BM, a first color filter CF1, a second color filter CF2, a first color compensation layer CPL1, a second color compensation layer pattern CPLb, and a second substrate 100b.

According to another embodiment of the present disclosure, the first electrode 180 provided in each of the 1-1 light emitting area EA1a and the 2-1 light emitting area EA2a can further include a connection electrode BE provided at one side thereof. For example, the first electrode 180 provided in the 1-1 light emitting area EA1a can have a connection electrode BE formed on one side, for example, on the left side thereof, and the first electrode 180 provided in the 2-1 light emitting area EA2a can have a connection electrode BE formed on one side, for example, on the right side thereof. Hereinafter, for convenience of description, the first electrode 180 and the connection electrode BE provided in the 2-1 light emitting area EA2a will be mainly described.

The connection electrode BE can be electrically connected to the source electrode SE 161 of the thin film transistor through the contact hole CH. Meanwhile, in some cases, the connection electrode BE can be connected to the drain electrode of the thin film transistor (see 162 of FIG. 5) through the contact hole CH.

According to another embodiment of the present disclosure, by forming the connection electrode BE in the first light emitting area EA1 to the fourth light emitting area EA4, the step area GA in the area where the connection electrode BE is formed can partially protrude in the direction of the transmissive area TA compared to the step area GA in the area where the connection electrode BE is not formed. For example, a distance from one end of the black matrix BM provided at the outermost side of the non-transmissive area NTA to one end of the step area GA, for example, the right end can be defined as a third distance d3. In this case, the third distance d3 can be greater than a second distance (see d2 in FIG. 14) from one end of the black matrix BM provided at the outermost side of the non-transmissive area NTA in the area where the connection electrode BE is not formed, for example, one end of the right end to one end of the step area GA, for example.

According to another embodiment of the present disclosure, a second color compensation layer pattern CPLb provided to partially protrude to one side of the first color compensation layer CPL1, for example, the right side, can be additionally formed so that the connection electrode BE is formed to correspond to the step area GA protruding in the direction of the transmissive area TA.

By the second color compensation layer pattern CPLb protruding from one side of the first color compensation layer CPL1, the step area GA provided in the area where the connection electrode BE is formed overlaps one of the first color compensation layer CPL1 and the second color compensation layer pattern CPLb. By forming in this way, the step area GA protruding to form the connection electrode BE, the first color compensation layer CPL1 and the second color compensation layer pattern CPLb overlap, thereby minimizing or mitigating a phenomenon in which light passing through the step area GA becomes yellowish, and further, a phenomenon in which the image of an object placed behind the rear surface of the transparent display device appears blurred can be improved by reducing diffraction of light passing through the step area GA.

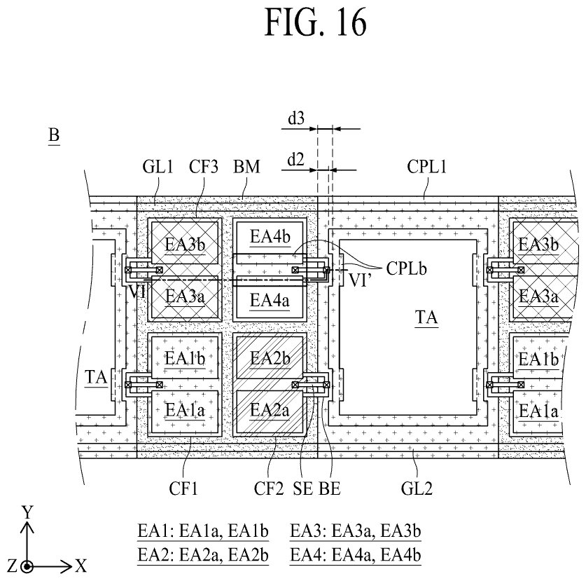

FIG. 16 is a plan view, enlarging area B of FIG. 3, illustrating a transparent display device according to another embodiment of the present disclosure. Meanwhile, an embodiment of FIG. 16 is the same as an embodiment of FIG. 4 except for configurations of a gate line, a connection electrode, a contact portion, and each light emitting area, thus different configurations will be mainly described below.

Referring to FIG. 16, the transparent display device according to an embodiment of the present disclosure can include the transmissive area TA and the first light emitting area EA1, the second light emitting area EA2, the third light emitting area EA3, and the fourth light emitting area EA4 provided on one side of the transmissive area TA, for example, on the left side.

A first gate line GL1 for supplying a gate signal to each of the third light emitting area EA3 and the fourth light emitting area EA4 can be formed on the third light emitting area EA3 and the fourth light emitting area EA4, and a second gate line GL2 for supplying a gate signal to the first light emitting area EA1 and the second light emitting area EA2 can be formed below the first light emitting area EA1 and the second light emitting area EA2.

According to another embodiment of the present disclosure, the first gate line GL1 and the second gate line GL2 can be provided to overlap the black matrix BM and the first color compensation layer CPL1.

As the first color compensation layer CPL1 overlaps the first gate line GL1 and the second gate line GL2, even if the light transmitted from the rear surface of the transparent display panel (refer to 100 in FIG. 2) is refracted or diffracted by a step formed in the first gate line GL1 or the second gate line GL2, a phenomenon in which the image of an object placed behind the rear surface of the transparent display panel (refer to 100 in FIG. 2) appears blurred can be minimized or eliminated.

Color filters CF1, CF2, and CF3 can be formed to correspond to the first light emitting area EA1, the second light emitting area EA2, and the third light emitting area EA3, respectively. For example, a first color filter CF1 for transmitting blue B light can be formed in the first light emitting area EA1, a second color filter CF2 for transmitting red R light can be formed in the second light emitting area EA2, and a third color filter CF3 for transmitting green G light can be formed in the third light emitting area EA3.

Accordingly, the light emitted from the first light emitting area EA1 can pass through the first color filter CF1 to display blue B, the light emitted from the second light emitting area EA2 can pass through the second color filter CF2 to display red R, and the light emitted from the third light emitting area EA3 can pass through the third color filter CF3 to display green G.

Meanwhile, a separate color filter may not be provided in the fourth light emitting area EA4. Accordingly, light emitted from the fourth light emitting area EA4 can display white W. The fourth light emitting area EA4 can be corresponding to a pixel providing white color light.

A black matrix BM for partitioning the first color filter CF1 to the third color filter CF3 can be formed around each of the first to fourth light emitting areas EA1 to EA4. The black matrix BM can be formed to overlap at least a portion of the first to fourth light emitting areas EA1 to EA4, but is not limited thereto.

According to another embodiment of the present disclosure, the first to fourth light emitting areas EA1 to EA4 can include two light emitting areas each connected by a connection electrode BE. For example, the first light emitting area EA1 can include the 1-1 light emitting area EA1a and the 1-2 light emitting area EA1b which are connected by a connection electrode BE. The second light emitting area EA2 can include the 2-1 light emitting area EA2a and the 2-2 light emitting area EA2b which are connected by a connection electrode BE. The third light emitting area EA3 can include the 3-1 light emitting area EA3a and the 3-2 light emitting area EA3b which are connected by a connection electrode BE. The fourth light emitting area EA4 can include the 4-1 light emitting area EA4a and the 4-2 light emitting area EA4b which are connected by a connection electrode BE.

The detailed structure of the connection electrode BE is the same as that described in FIG. 13, detailed description is not duplicated. The connection electrode BE is an element that recovers a defect occurring in one of the two light emitting areas configuring the first light emitting area EA1. For example, the connection between any one light emitting area having the defect and the connection electrode BE can be disconnected, and only the normal light emitting area can be kept in contact with the connection electrode BE. As a result, the entire light emitting area is not darkened, and only half of the light emitting area can be darkened.

Since the connection electrode BE is disposed in each light emitting area EA1 to EA4, a part of the step area (GA in FIG. 5) can further protrude into the transmission area TA. For example, referring to the fourth light emitting area EA4, the step area in the area where the connection electrode BE is formed can be formed to further protrude in a direction of the transmission area TA compared to the step area in the area where the connection electrode BE is not formed. For example, in the area where the connection electrode BE is not formed, the step area is spaced apart from one end of the black matrix BM by a second distance d2, whereas the step area is spaced apart from one end of the black matrix BM by a third distance d3. In this case, the second distance d2 can be smaller than the third distance d3.

According to another embodiment of the present disclosure, a second color compensation layer pattern CPLb can be additionally formed in a partial region of the first color compensation layer CPL1 to cover the step area protruding from the region where the connection electrode BE is formed by a third distance d3. The second color compensation layer CPLb can have a shape that protrudes and extends from the first color compensation layer CPL1 in the direction of the transmission area TA so as to completely cover the connection electrode BE. By forming in this way, the degree of refraction or diffraction of light incident from the rear surface of the transparent display device in the step area protruding from the region where the connection electrode BE is formed is reduced, so that a phenomenon in which the image of an object placed behind the rear surface of the transparent display device appears blurred can be overcome, and visibility of the user can be improved.

Each of the first light emitting area EA1, the second light emitting area EA2 and the third light emitting area EA3 includes two light emitting areas connected by a connection electrode BE. In each of the light emitting areas EA1, EA2 and EA3, the first electrode 180 is divided into two parts. The light passing through the separated portion of the first electrode 180 can be diffracted so the image after passing through the separated portion of the first electrode 180 may be blurred. However, each of the first light emitting area EA1, the second light emitting area EA2 and the third light emitting area EA3 is covered by any one of color filter. That is, the separated portion of the first electrode 180 is covered by the color filter. As the result, even when the diffraction is occurred at the separated portion of the first electrode 180, the phenomena of the blurred image can be reduced by the color filter.

However, in the fourth light emitting area EA4 where there is no color filter, the diffraction can cause the blurred image problem. For example, the fourth light emitting area EA4 has the 4-1 light emitting area EA4a and the 4-2 light emitting area EA4b. Each of the 4-1 light emitting area EA4a and the 4-2 light emitting area EA4b has the separated first electrode 180. Further, there is no color filter, so the light passing through the separated portion of the first electrode 180 can generate a blurred image due to the diffraction effect. To solve this problem, in the embodiment according to FIG. 16, the second color compensation pattern CPLb is disposed between the 4-1 light emitting area EA4a and the 4-2 light emitting area EA4b within the fourth light emitting area EA4. Here, it is preferable that the second color compensation pattern CPLb can have width enough to cover all areas including the separation portions between the 4-1 light emitting area EA4a and the 4-2 light emitting area EA4b, the connection electrode BE, the source electrode SE, and contact hole connecting the source electrode SE to the connecting electrode BE.

It is preferable that the width of the second color compensation layer CPLb has enough width to cover the area between the 4-1 light emitting area EA4a and the 4-2 light emitting area EA4b after joining the first substrate 100a and the second substrate 100b. When an alignment error is occurred as attaching the second substrate 100b having the color filter and the first substrate 100a having the light emitting elements, the second color compensation pattern CPLb may not cover the separation portion between the 4-1 light emitting area EA4a and the 4-2 light emitting area EA4b. As the result, the light passing through the separation portion of the first electrode 180 may have a diffraction phenomenon.

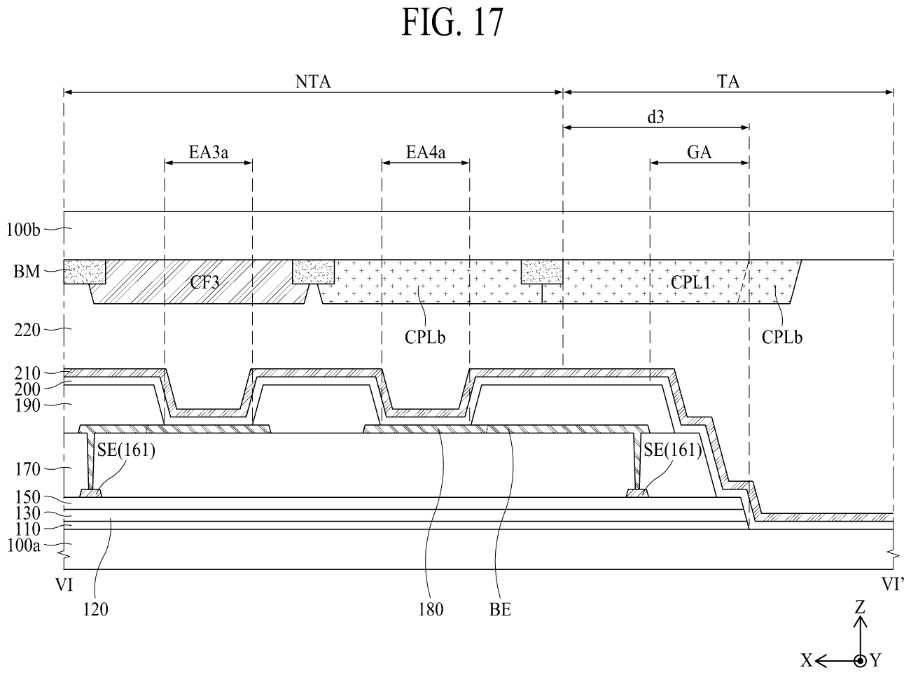

The second color compensation layer pattern CPLb can include the same material as the first color compensation layer CPL1. Further, the second color compensation layer pattern CPLb and the first color compensation layer CPL1 can have the same material as the first color filter CF1 representing the blue color. Meanwhile, the second color compensation layer pattern CPLb will be described in more detail with reference to FIG. 17.

FIG. 17 is a cross sectional view of a transparent display device according to another embodiment of the present disclosure. In this case, FIG. 17 corresponds to a cross-sectional view along line VI-VI′ of FIG. 16. FIG. 17 relates to the fourth light emitting area EA4 and the transmission area TA. In the following description of the embodiment shown in FIG. 17, the same parts as the embodiment of FIG. 5 will be omitted, and the description will focus on the different configurations.

Referring to FIG. 17, the transparent display device according to another embodiment of the present disclosure can include a first substrate 100a and a second substrate 100b which are joined together. The first substrate 100a can include a buffer layer 110, a gate insulating layer 130, an interlayer insulating layer 150, a source electrode SE 161, a planarization layer 170, a first electrode 180, a connection electrode BE, a bank 190, a light emitting layer 200 and a second electrode 210. The second substrate 100b can include a black matrix BM, a third color filter CF3, a first color compensation layer CPL1, a second color compensation layer pattern CPLb and an encapsulation layer 220. The transparent display device is formed by joining the first substrate 100a and the second substrate 100b as attaching the second electrode 210 to the encapsulation layer 220 each other.

According to another embodiment of the present disclosure, the first electrode 180 provided in each of the 4-1 light emitting area EA4a and the 4-2 light emitting area EA4b can further include a connection electrode BE provided at one side thereof. For example, the first electrode 180 provided in the 4-1 light emitting area EA4a can have a connection electrode BE formed on one side, for example, on the right side thereof. Hereinafter, for convenience of description, the first electrode 180 and the connection electrode BE provided in the 4-1 light emitting area EA4a will be mainly described.

The connection electrode BE can be electrically connected to the source electrode SE 161 of the thin film transistor through the contact hole CH. Meanwhile, in some cases, the connection electrode BE can be connected to the drain electrode of the thin film transistor through the contact hole CH.

According to another embodiment of the present disclosure, by forming the connection electrode BE in the first light emitting area EA1 to the fourth light emitting area EA4, the step area GA in the area where the connection electrode BE is formed can partially protrude in the direction of the transmissive area TA compared to the step area GA in the area where the connection electrode BE is not formed. For example, a distance from the right end of the black matrix BM provided at the outermost side of the non-transmissive area NTA to the right end of the step area GA can be defined as a third distance d3. In this case, the third distance d3 can be greater than a second distance from one end of the black matrix BM provided at the outermost side of the non-transmissive area NTA in the area where the connection electrode BE is not formed, for example, one end of the right end to one end of the step area GA, for example.

According to another embodiment of the present disclosure, a second color compensation layer pattern CPLb provided to partially protrude to one side of the first color compensation layer CPL1, for example, to the right, can be additionally formed so that the connection electrode BE is formed to correspond to the step area GA protruding in the direction of the transmissive area TA.

By the second color compensation layer pattern CPLb protruding from one side of the first color compensation layer CPL1, the step area GA provided in the area where the connection electrode BE is formed overlaps one of the first color compensation layer CPL1 and the second color compensation layer pattern CPLb. By forming in this way, the step area GA protruding to form the connection electrode BE, the first color compensation layer CPL1 and the second color compensation layer pattern CPLb overlap, thereby minimizing a phenomenon in which light passing through the step area GA becomes yellowish, and further, a phenomenon in which the image of an object placed behind the rear surface of the transparent display device appears blurred can be overcome by reducing diffraction of light passing through the step area GA.

In addition, at the fourth light emitting area EA4, a white pixel, can include a second color compensation layer pattern CPLb. For example, the second color compensation layer pattern CPLb is disposed between the 4-1 light emitting area EA4a and the 4-2 light emitting area EA4b within the fourth light emitting area EA4. FIG. 17 is a cross-sectional view of the portion covered by the second color compensation layer pattern CPLb in the 4-1 light emitting area EA4a shown in FIG. 16.

The second color compensation layer pattern CPLb can be formed as covering whole width of the fourth light emitting area EA4. For example, the second color compensation layer pattern CPLb can be arranged in the same way as the third color filter CF3 in the third emission area EA3. The different feature is that the third color filter CF3 covers the entire third light emitting area EA3, but the second color filter layer pattern CPLb is placed only between the 4-1 light emitting area EA4a and the 4-2 light emitting area EA4b.

The second color compensation layer pattern CPLb can be made of the same material as the first color compensation layer CPL1. Further, the first color compensation layer CPL1 can be made of the same material with the blue color filter. Therefore, the second color compensation layer pattern CPLb and the first color compensation layer CPL1 can be formed of a blue color filter disposed at the first light emitting area EA1.

As the result, between the 4-1 light emitting area EA4a and the 4-2 light emitting area EA4b, the second color compensation layer pattern CPLb covers the divided portion of the first electrode 180. Accordingly, even when diffraction occurs in light at the part where the first electrode 180 is separated, the blurred image problem can be reduced or eliminated by the second color compensation layer pattern CPLb.

In the embodiment according to FIG. 16, the black matrix BM is disposed around the transmissive area TA. However, it is not limited thereto, and can have a structure in which the black matrix BM is selectively removed between the white pixel EA4 and the transmissive area TA.

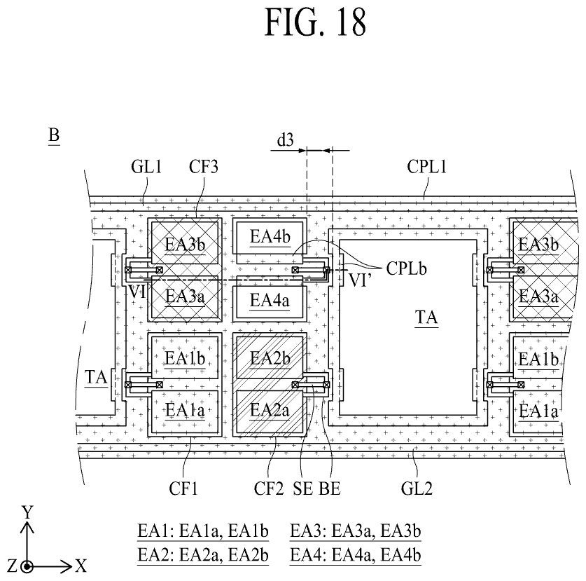

FIG. 18 is a plan view, enlarging area B of FIG. 3, illustrating a transparent display device according to another embodiment of the present disclosure. Meanwhile, an embodiment of FIG. 18 is the same as an embodiment of FIG. 4 except for configurations of a gate line, a connection electrode, a contact portion, and each light emitting area, thus different configurations will be mainly described below.

Referring to FIG. 18, the transparent display device according to an embodiment of the present disclosure can include the transmissive area TA and the first light emitting area EA1, the second light emitting area EA2, the third light emitting area EA3, and the fourth light emitting area EA4 provided on one side of the transmissive area TA, for example, on the left side. Since the structure on the plan view is the same as that described in FIG. 16, detailed description is not duplicated.

The embodiment of the present disclosure according to FIG. 18, unlike FIG. 16, does not have a black matrix. Therefore, the first gate line GL1 and the second gate line GL2 can overlap with the first color compensation layer CPL1. As the first color compensation layer CPL1 overlaps the first gate line GL1 and the second gate line GL2, even if the light transmitted from the rear surface of the transparent display panel (refer to 100 in FIG. 2) is refracted or diffracted by a step formed in the first gate line GL1 or the second gate line GL2, a phenomenon in which the image of an object behind the rear surface of the transparent display panel (refer to 100 in FIG. 2) appears blurred can be minimized or eliminated.

Color filters CF1, CF2, and CF3 can be formed to correspond to the first light emitting area EA1, the second light emitting area EA2, and the third light emitting area EA3, respectively. For example, a first color filter CF1 for transmitting blue B light can be formed in the first light emitting area EA1. A second color filter CF2 for transmitting red R light can be formed in the second light emitting area EA2. A third color filter CF3 for transmitting green G light can be formed in the third light emitting area EA3. Accordingly, the light emitted from the first light emitting area EA1 can pass through the first color filter CF1 to display blue B, the light emitted from the second light emitting area EA2 can pass through the second color filter CF2 to display red R, and the light emitted from the third light emitting area EA3 can pass through the third color filter CF3 to display green G.

Meanwhile, a separate color filter may not be provided in the fourth light emitting area EA4. Accordingly, light emitted from the fourth light emitting area EA4 can display white W.

A first color compensation layer CPL1 for partitioning the first color filter CF1 to the third color filter CF3 can be formed around each of the first to fourth light emitting areas EA1 to EA4.

According to another embodiment of the present disclosure, the first to fourth light emitting areas EA1 to EA4 can include two light emitting areas each connected by a connection electrode BE. For example, the first light emitting area EA1 can include the 1-1 light emitting area EA1a and the 1-2 light emitting area EA1b which are connected by a connection electrode BE. The second light emitting area EA2 can include the 2-1 light emitting area EA2a and the 2-2 light emitting area EA2b which are connected by a connection electrode BE. The third light emitting area EA3 can include the 3-1 light emitting area EA3a and the 3-2 light emitting area EA3b which are connected by a connection electrode BE. The fourth light emitting area EA4 can include the 4-1 light emitting area EA4a and the 4-2 light emitting area EA4b which are connected by a connection electrode BE.

The detailed structure of the connection electrode BE is the same as that described in FIG. 16, detailed description is not duplicated. Since the connection electrode BE is disposed in each light emitting area EA1 to EA4, a part of the step area (GA in FIG. 5) can further protrude into the transmission area TA.

According to another embodiment of the present disclosure, a second color compensation layer pattern CPLb can be additionally formed in a partial region of the first color compensation layer CPL1 to cover the step area protruding from the region where the connection electrode BE is formed by a third distance d3. The second color compensation layer CPLb can have a shape that protrudes and extends from the first color compensation layer CPL1 in the direction of the transmission area TA so as to completely cover the connection electrode BE. By forming in this way, the degree of refraction or diffraction of light incident from the rear surface of the transparent display device in the step area protruding from the region where the connection electrode BE is formed is reduced, so that a phenomenon in which the image of an object placed behind the rear surface of the transparent display device appears blurred can be overcome, and visibility of the user can be improved.

Each of the first light emitting area EA1, the second light emitting area EA2 and the third light emitting area EA3 includes two light emitting areas connected by a connection electrode BE. In each of the light emitting areas EA1, EA2 and EA3, the first electrode 180 is divided into two parts. The light passing through the separated portion of the first electrode 180 can be diffracted so the image after passing through the separated portion of the first electrode 180 may be blurred. However, each of the first light emitting area EA1, the second light emitting area EA2 and the third light emitting area EA3 is covered by any one of color filter. That is, the separated portion of the first electrode 180 is covered by the color filter. As the result, even when the diffraction occurred at the separated portion of the first electrode 180, the phenomena of the blurred image can be reduced by the color filter.

However, in the fourth light emitting area EA4 where there is no color filter, the diffraction can cause the blurred image problem. For example, the fourth light emitting area EA4 has the 4-1 light emitting area EA4a and the 4-2 light emitting area EA4b. Each of the 4-1 light emitting area EA4a and the 4-2 light emitting area EA4b has the separated first electrode 180. Further, there is no color filter, so the light passing through the separated portion of the first electrode 180 can generate a blurred image due to the diffraction effect. To solve this problem, in the embodiment according to FIG. 18, the second color compensation pattern CPLb is disposed between the 4-1 light emitting area EA4a and the 4-2 light emitting area EA4b within the fourth light emitting area EA4. Here, it is preferable that the second color compensation pattern CPLb can have width enough to cover all areas including the separation portions between the 4-1 light emitting area EA4a and the 4-2 light emitting area EA4b, the connection electrode BE, the source electrode SE, and contact hole connecting the source electrode SE to the connecting electrode BE.

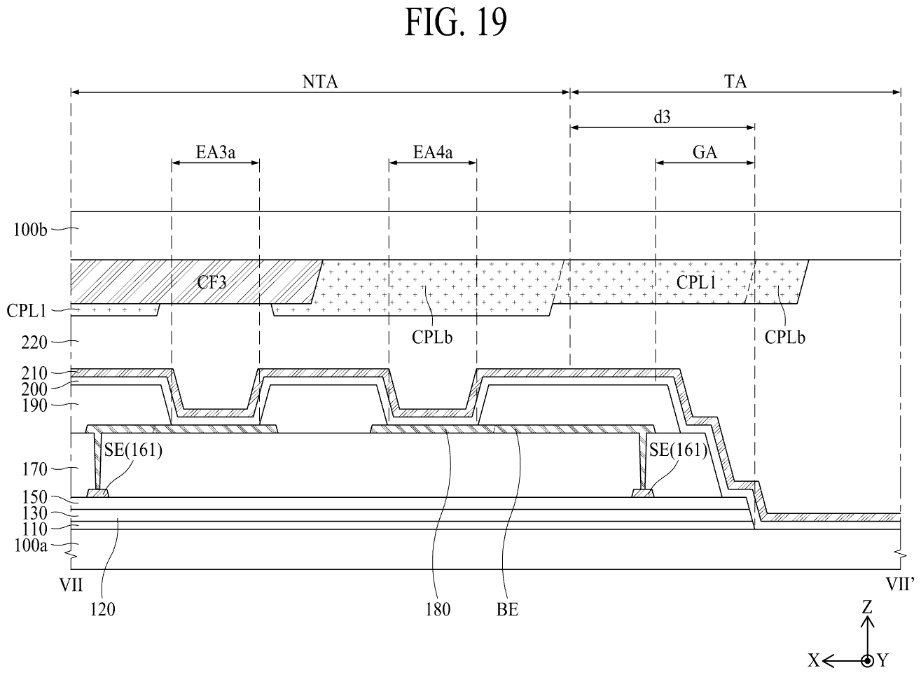

The second color compensation layer pattern CPLb can include the same material as the first color compensation layer CPL1. Further, the second color compensation layer pattern CPLb and the first color compensation layer CPL1 can have the same material as the first color filter CF1 representing the blue color. Meanwhile, the second color compensation layer pattern CPLb will be described in more detail with reference to FIG. 19.

FIG. 19 is a cross sectional view of a transparent display device according to another embodiment of the present disclosure. In this case, FIG. 19 corresponds to a cross-sectional view along line VII-VII′ of FIG. 18. FIG. 19 relates to the fourth light emitting area EA4 and the transmission area TA. In the following description of the embodiment shown in FIG. 19, the same parts as the embodiment of FIG. 17 will be omitted, and the description will focus on the different configurations.

Referring to FIG. 19, the transparent display device according to another embodiment of the present disclosure can include a first substrate 100a and a second substrate 100b which are joined together. The first substrate 100a can include a buffer layer 110, a gate insulating layer 130, an interlayer insulating layer 150, a source electrode SE 161, a planarization layer 170, a first electrode 180, a connection electrode BE, a bank 190, a light emitting layer 200 and a second electrode 210. The second substrate 100b can include a black matrix BM, a third color filter CF3, a first color compensation layer CPL1, a second color compensation layer pattern CPLb and an encapsulation layer 220. The transparent display device is formed by joining the first substrate 100a and the second substrate 100b as attaching the second electrode 210 to the encapsulation layer 220 each other.

According to another embodiment of the present disclosure, the first electrode 180 provided in each of the 4-1 light emitting area EA4a and the 4-2 light emitting area EA4b can further include a connection electrode BE provided at one side thereof. For example, the first electrode 180 provided in the 4-1 light emitting area EA4a can have a connection electrode BE formed on one side, for example, on the right side thereof. Hereinafter, for convenience of description, the first electrode 180 and the connection electrode BE provided in the 4-1 light emitting area EA4a will be mainly described.

According to another embodiment of the present disclosure, by forming the connection electrode BE in the first light emitting area EA1 to the fourth light emitting area EA4, the step area GA in the area where the connection electrode BE is formed can partially protrude in the direction of the transmissive area TA compared to the step area GA in the area where the connection electrode BE is not formed. For example, a distance from the one end of the fourth light emitting area EA4 provided at the outermost side of the non-transmissive area NTA to the right end of the step area GA can be defined as a third distance d3.

According to another embodiment of the present disclosure, a second color compensation layer pattern CPLb provided to partially protrude to one side of the first color compensation layer CPL1, for example, to the right, can be additionally formed so that the connection electrode BE is formed to correspond to the step area GA protruding in the direction of the transmissive area TA.

By the second color compensation layer pattern CPLb protruding from one side of the first color compensation layer CPL1, the step area GA provided in the area where the connection electrode BE is formed overlaps one of the first color compensation layer CPL1 and the second color compensation layer pattern CPLb. By forming in this way, the step area GA protruding to form the connection electrode BE, the first color compensation layer CPL1 and the second color compensation layer pattern CPLb overlap, thereby minimizing a phenomenon in which light passing through the step area GA becomes yellowish, and further, a phenomenon in which the image of an object placed behind the rear surface of the transparent display device appears blurred can be overcome by reducing diffraction of light passing through the step area GA.

In addition, at the fourth light emitting area EA4, a white pixel, can include a second color compensation layer pattern CPLb. For example, the second color compensation layer pattern CPLb is disposed between the 4-1 light emitting area EA4a and the 4-2 light emitting area EA4b within the fourth light emitting area EA4. FIG. 19 is a cross-sectional view of the portion covered by the second color compensation layer pattern CPLb in the 4-1 light emitting area EA4a shown in FIG. 18.

The second color compensation layer pattern CPLb is disposed only between the 4-1 light emitting area EA4a and the 4-2 light emitting area EA4b. The second color compensation layer pattern CPLb can be made of the same material as the first color compensation layer CPL1. Further, the second color compensation layer pattern CPLb and the first color compensation layer CPL1 can be formed of a blue color filter disposed at the first light emitting area EA1.

As the result, between the 4-1 light emitting area EA4a and the 4-2 light emitting area EA4b, the second color compensation layer pattern CPLb covers the divided portion of the first electrode 180. Accordingly, even when diffraction occurs in light at the part where the first electrode 180 is separated, the blurred image problem can be reduced or eliminated by the second color compensation layer pattern CPLb.

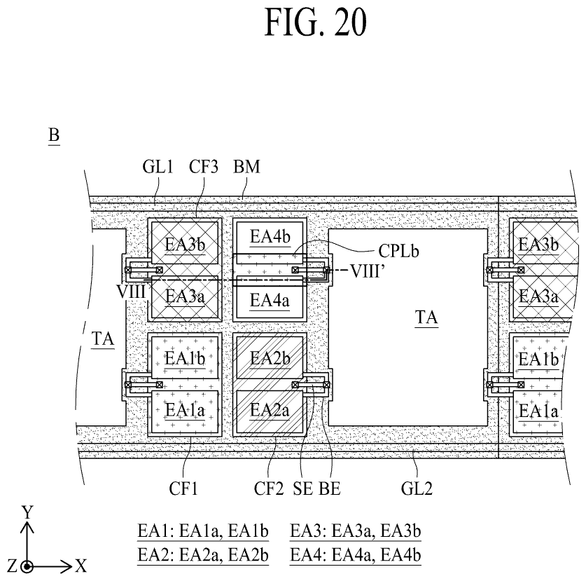

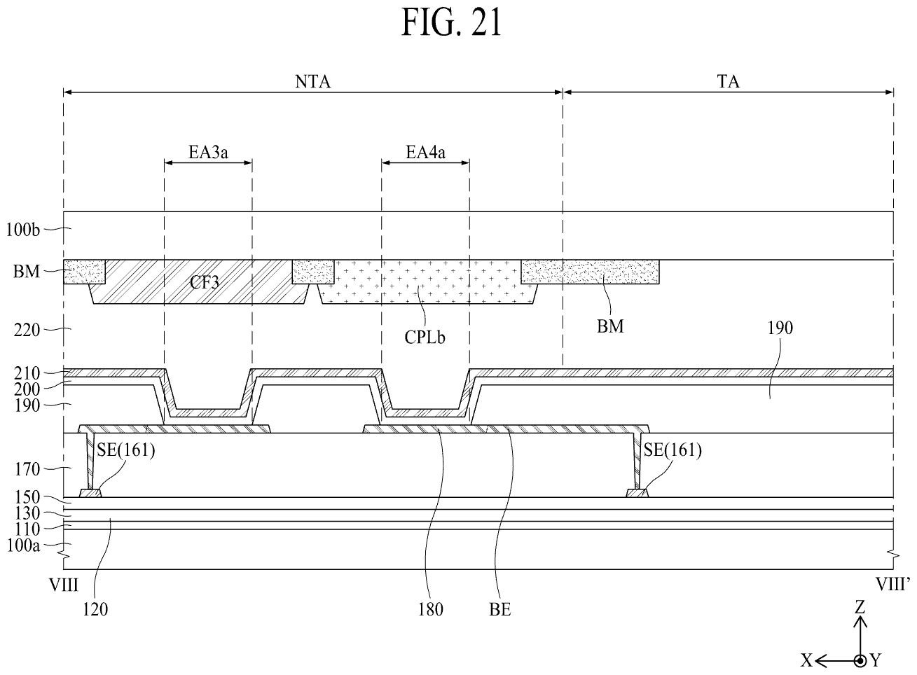

FIG. 20 is a plan view, enlarging area B of FIG. 3, illustrating a transparent display device according to another embodiment of the present disclosure. FIG. 21 is a cross-sectional view, along line VIII-VIII′ of FIG. 20, illustrating a transparent display device according to another embodiment of the present disclosure. Meanwhile, an embodiment shown in FIG. 20 and FIG. 21 is the same as an embodiment shown in FIG. 16 and FIG. 17 except for the exclusion of step area, thus different configuration will be mainly described below.

Referring to FIG. 20 and FIG. 21, the transparent display device according to an embodiment of the present disclosure can include a transmissive area TA and the first light emitting area EA1, the second light emitting area EA2, the third light emitting area EA3, and the fourth light emitting area EA4 provided on one side of the transmissive area TA, for example, on the left side.

The embodiment of the present disclosure according to FIG. 20 and FIG. 21, unlike the embodiment according to FIG. 16 and FIG. 17, does not have step area near the transmissive area TA. Therefore, the first gate line GL1 and the second gate line GL2 can be disposed as being overlapped with the black matrix BM. As the first gate line GL1 and the second gate line GL2 overlap the black matrix BM, even if the light transmitted from the rear surface of the transparent display panel (refer to 100 in FIG. 2) is refracted or diffracted by a step formed by the first gate line GL1 or the second gate line GL2, a phenomenon in which the image of an object placed behind the rear surface of the transparent display panel (refer to 100 in FIG. 2) appears blurred can be minimized or eliminated.

Color filters CF1, CF2, and CF3 can be formed to correspond to the first light emitting area EA1, the second light emitting area EA2, and the third light emitting area EA3, respectively. For example, a first color filter CF1 for transmitting blue B light can be formed in the first light emitting area EA1. A second color filter CF2 for transmitting red R light can be formed in the second light emitting area EA2. A third color filter CF3 for transmitting green G light can be formed in the third light emitting area EA3. Meanwhile, a separate color filter may not be provided in the fourth light emitting area EA4. Accordingly, light emitted from the fourth light emitting area EA4 can display white W. The black matrix BM for partitioning the first color filter CF1 to the third color filter CF3 can be disposed around each of the first to fourth light emitting areas EA1 to EA4.

According to another embodiment of the present disclosure, the first to fourth light emitting areas EA1 to EA4 can include two light emitting areas each connected by a connection electrode BE. For example, the first light emitting area EA1 can include the 1-1 light emitting area EA1a and the 1-2 light emitting area EA1b which are connected by a connection electrode BE. The second light emitting area EA2 can include the 2-1 light emitting area EA2a and the 2-2 light emitting area EA2b which are connected by a connection electrode BE. The third light emitting area EA3 can include the 3-1 light emitting area EA3a and the 3-2 light emitting area EA3b which are connected by a connection electrode BE. The fourth light emitting area EA4 can include the 4-1 light emitting area EA4a and the 4-2 light emitting area EA4b which are connected by a connection electrode BE.

The detailed structure of the connection electrode BE is the same as that described in FIG. 16 and FIG. 17, detailed description is not duplicated. Since the connection electrode BE is disposed in each light emitting area EA1 to EA4, a part of the step area (GA in FIG. 5) can further protrude into the transmission area TA.

According to another embodiment of the present disclosure, the black matrix BM can be formed in a shape that protrudes toward the transmissive area TA so as to cover the step area that protrudes toward the transmissive area TA in the area where the connection electrode BE is formed. By forming in this way, the degree of refraction or diffraction of light incident from the rear surface of the transparent display device in the step area protruding from the region where the connection electrode BE is formed is reduced, so that a phenomenon in which the image of an object placed behind the rear surface of the transparent display device appears blurred can be overcome, and visibility of the user can be improved.

Each of the first light emitting area EA1, the second light emitting area EA2 and the third light emitting area EA3 includes two light emitting areas connected by a connection electrode BE. In each of the light emitting areas EA1, EA2 and EA3, the first electrode 180 is divided into two parts. The light passing through the separated portion of the first electrode 180 can be diffracted so the image after passing through the separated portion of the first electrode 180 may be blurred. However, each of the first light emitting area EA1, the second light emitting area EA2 and the third light emitting area EA3 is covered by any one of color filter. That is, the separated portion of the first electrode 180 is covered by the color filter. As the result, even when the diffraction occurred at the separated portion of the first electrode 180, the phenomena of the blurred image can be reduced by the color filter.

However, in the fourth light emitting area EA4 where there is no color filter, the diffraction can cause the blurred image problem. For example, the fourth light emitting area EA4 has the 4-1 light emitting area EA4a and the 4-2 light emitting area EA4b. Each of the 4-1 light emitting area EA4a and the 4-2 light emitting area EA4b has the separated first electrode 180. Further, there is no color filter, so the light passing through the separated portion of the first electrode 180 can generate a blurred image due to the diffraction effect.

To solve this problem, in the embodiment according to FIG. 20 and FIG. 21, the second color compensation pattern CPLb is disposed between the 4-1 light emitting area EA4a and the 4-2 light emitting area EA4b within the fourth light emitting area EA4. Here, it is preferable that the second color compensation pattern CPLb can have width enough to cover all area of separation portions between the 4-1 light emitting area EA4a and the 4-2 light emitting area EA4b and some of the connection electrode BE. Further, the source electrode SE and the contact hole connecting the source electrode SE to the connection electrode BE can be covered by the black matrix BM. The second color compensation pattern CPLb can be made of the same material with the first color filter CF1 representing blue color.

The transparent display device according to another embodiment of the present disclosure according to FIG. 20 and FIG. 21 has no step area, and has a structure that prevents the problem due to the diffraction phenomenon by using a black matrix BM. However, in the fourth light emitting area EA4, the first electrode 180 is divided into two areas, so diffraction can still exist due to a step difference occurring in the divided area. To prevent this diffraction problem, the area where the first electrode 180 is separated in the fourth light emitting area EA4, which is a white pixel, is covered by the second color compensation layer pattern CPLb. As a result, a phenomenon in which the image of an object placed behind the rear surface of the transparent display device appears blurred can be overcome by reducing diffraction of light passing through the separated area of the first electrode 180.

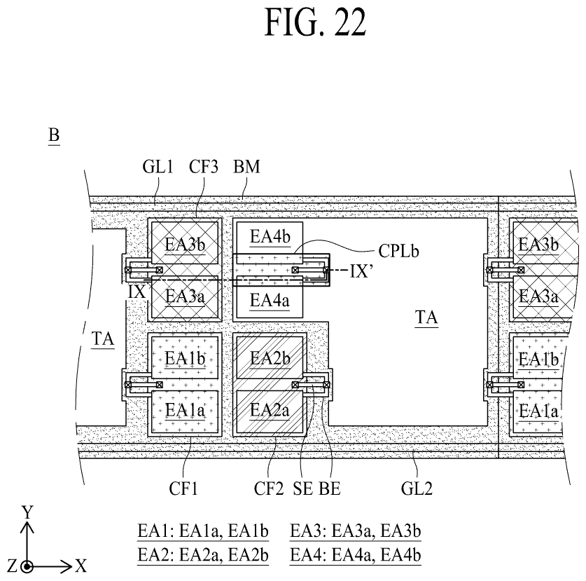

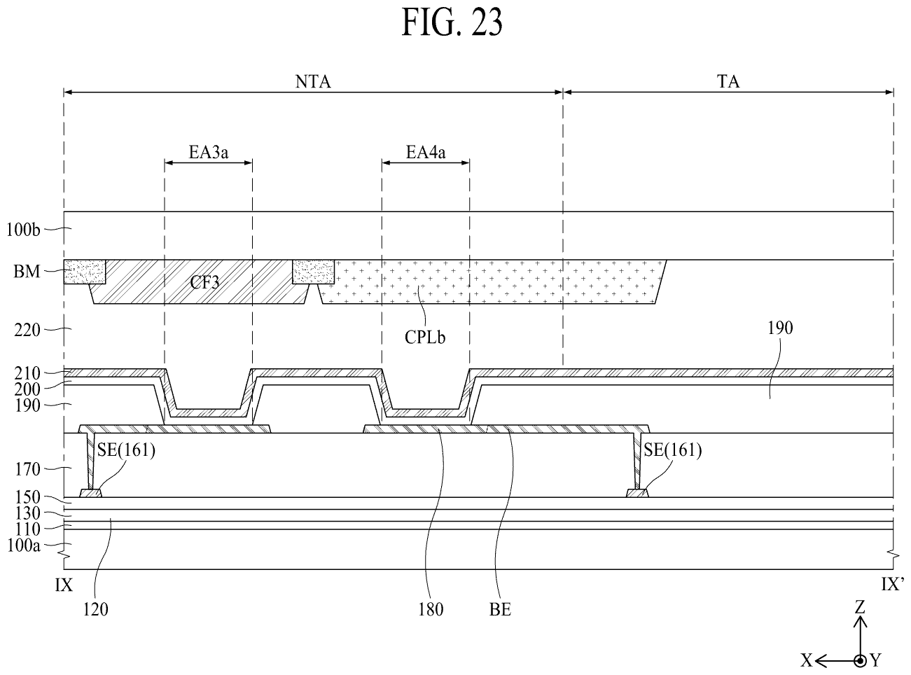

FIG. 22 is a plan view, enlarging area B of FIG. 3, illustrating a transparent display device according to another embodiment of the present disclosure. FIG. 23 is a cross-sectional view, along line IX-IX′ of FIG. 22, illustrating a transparent display device according to another embodiment of the present disclosure.

Referring to FIG. 20 and FIG. 21, the transparent display device according to an embodiment of the present disclosure can include a transmissive area TA and a light emitting area. The light emitting area can include a first light emitting area EA1, a second light emitting area EA2, a third light emitting area EA3 and a fourth light emitting area EA4 provided on one side of the transmissive area TA, for example, on the left side.

The embodiment of the present disclosure according to FIG. 20 and FIG. 21, unlike the embodiment according to FIG. 16 and FIG. 17, does not have step area near the transmissive area TA. Therefore, the first gate line GL1 and the second gate line GL2 can be disposed as being overlapped with the black matrix BM. As the first gate line GL1 and the second gate line GL2 overlap the black matrix BM, even if the light transmitted from the rear surface of the transparent display panel (refer to 100 in FIG. 2) is refracted or diffracted by a step formed by the first gate line GL1 or the second gate line GL2, a phenomenon in which the image of an object placed behind the rear surface of the transparent display panel (refer to 100 in FIG. 2) appears blurred can be minimized or eliminated.

Color filters CF1, CF2, and CF3 can be formed to correspond to the first light emitting area EA1, the second light emitting area EA2, and the third light emitting area EA3, respectively. For example, a first color filter CF1 for transmitting blue B light can be formed in the first light emitting area EA1. A second color filter CF2 for transmitting red R light can be formed in the second light emitting area EA2. A third color filter CF3 for transmitting green G light can be formed in the third light emitting area EA3. Meanwhile, a separate color filter may not be provided in the fourth light emitting area EA4. Accordingly, light emitted from the fourth light emitting area EA4 can display white W. The black matrix BM for partitioning the first color filter CF1 to the third color filter CF3 can be disposed around each of the first to fourth light emitting areas EA1 to EA4. However, the black matrix BM is not disposed between the fourth light emitting area EA4 and the transmissive area TA. Therefore, the area of transmissive area TA can be maximized, so the light transmittance can be further increased.

The transparent display device according to another embodiment of the present disclosure as shown in FIG. 22 and FIG. 23 can have very similar structure with the transparent display device shown in FIG. 20 and FIG. 21. The different feature is that on the structure of the black matrix BM. Therefore, the detailed description of the same structure is not duplicated. For a description of the configuration having the same structure, it can be referred to the description of the transparent display device shown in FIG. 20 and FIG. 21.

The first to fourth light emitting areas EA1 to EA4 can include two light emitting areas each connected by a connection electrode BE. For example, the first light emitting area EA1 can include the 1-1 light emitting area EA1a and the 1-2 light emitting area EA1b which are connected by a connection electrode BE. The second light emitting area EA2 can include the 2-1 light emitting area EA2a and the 2-2 light emitting area EA2b which are connected by a connection electrode BE. The third light emitting area EA3 can include the 3-1 light emitting area EA3a and the 3-2 light emitting area EA3b which are connected by a connection electrode BE. The fourth light emitting area EA4 can include the 4-1 light emitting area EA4a and the 4-2 light emitting area EA4b which are connected by a connection electrode BE.

Each of the first light emitting area EA1, the second light emitting area EA2 and the third light emitting area EA3 includes two light emitting areas connected by a connection electrode BE. In each of the light emitting areas EA1, EA2 and EA3, the first electrode 180 is divided into two parts. The light passing through the separated portion of the first electrode 180 can be diffracted so the image after passing through the separated portion of the first electrode 180 may be blurred. However, each of the first light emitting area EA1, the second light emitting area EA2 and the third light emitting area EA3 is covered by any one of color filter. That is, the separated portion of the first electrode 180 is covered by the color filter. As the result, even when the diffraction occurred at the separated portion of the first electrode 180, the phenomena of the blurred image can be reduced by the color filter.

However, in the fourth light emitting area EA4 where there is no color filter, the diffraction can cause the blurred image problem. For example, the fourth light emitting area EA4 has the 4-1 light emitting area EA4a and the 4-2 light emitting area EA4b. Each of the 4-1 light emitting area EA4a and the 4-2 light emitting area EA4b has the separated first electrode 180. Further, there is no color filter, so the light passing through the separated portion of the first electrode 180 can generate a blurred image due to the diffraction effect.

To solve this problem, in the embodiment according to FIG. 20 and FIG. 21, the second color compensation pattern CPLb is disposed between the 4-1 light emitting area EA4a and the 4-2 light emitting area EA4b within the fourth light emitting area EA4. Here, it is preferable that the second color compensation pattern CPLb can have width enough to cover all areas including the separation portions between the 4-1 light emitting area EA4a and the 4-2 light emitting area EA4b, the connection electrode BE, the source electrode SE, and contact hole connecting the source electrode SE to the connecting electrode BE. As a result, a phenomenon in which the image of an object placed behind the rear surface of the transparent display device appears blurred can be overcome by reducing diffraction of light passing through the separated area of the first electrode 180. The second color compensation pattern CPLb can be made of the same material with the first color filter CF1 representing blue color.

Accordingly, various aspects of the present disclosure can have the following advantages.

According to an embodiment of the present disclosure, by forming a color compensation layer for transmitting light of a certain wavelength band to overlap the step area formed at the boundary of the transmission region, a phenomenon in which light passing through the transmission region becomes yellowish by light refracted from the step area can be alleviated or removed. In addition, as the degree to which the light passing through the rear surface of the transparent display panel in the step area is diffracted is reduced, the background of the rear surface can be seen more clearly. Through this, the user's visual sense can be improved.

According to an embodiment of the present disclosure, by forming a color compensation layer for transmitting light of a certain wavelength band on the step area formed at the boundary of the transmissive area, it is possible to minimize the yellowing of light passing through the transmissive area, and to reduce the diffraction of light passing through the transmissive area, thereby improving the blurring of the rear surface of the transparent display device. Even when a fine error occurs when the first substrate and the second substrate are bonded, the yellowing of the light passing through the transmissive area is alleviated or eliminated, or the diffraction of light passing through the transmissive area is reduced, so that the rear surface of the transparent display device appears blurred.

According to an embodiment of present disclosure, by dividing each color filter using a color compensation layer instead of a black matrix that divides the color filter, it is possible to improve the visibility of light passing through the transmission area without adding a mask by forming a color filter in the same process as the color filter formation process that transmits blue B.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A transparent display device comprising:
a substrate including a transmissive area and a non-transmissive area;
a first light emitting area disposed on the non-transmissive area;
a first color filter disposed in the non-transmissive area and the first color filter corresponding to the first light emitting area;
a step area disposed at a boundary area between the transmissive area and the non-transmissive area; and
a first color compensation layer disposed in the transmissive area to overlap the step area.

2. The transparent display device according to claim 1,
wherein for the first color compensation layer, a transmittance of light in a wavelength range being equal to or greater than 380 nm and less than 500 nm is greater than a transmittance of light in a wavelength range being equal to or greater 500 nm and less than 780 nm, and
wherein the transmittance of light in the wavelength range being equal to or greater than 380 nm and less than 500 nm is equal to or greater than about 20%.

3. The transparent display device according to claim 1,
wherein the first color compensation layer is disposed on a same layer as the first color filter.

4. The transparent display device according to claim 1, further comprising:
a first insulating layer disposed in the non-transmissive area and on the substrate; and
a bank disposed on the first insulating layer and defining the first light emitting area,
wherein one end of the first insulating layer and one end of the bank are disposed in the step area.

5. The transparent display device according to claim 1,
wherein the first color compensation layer is disposed at a lower height than the first color filter, and the first color compensation layer is in contact with a portion of an upper surface of the substrate.

6. The transparent display device according to claim 5, further comprising:
a first insulating layer disposed in the non-transmissive area and on the substrate; and
a bank disposed on the first insulating layer and defining the first light emitting area,
wherein one end of the first insulating layer and one end of the bank are disposed in the step area.

7. The transparent display device according to claim 6,
wherein the first color compensation layer is disposed to cover one side surface of the first insulating layer, one side surface of the bank, and an upper surface of the bank.

8. The transparent display device according to claim 1, further comprising:
a black matrix disposed between the first color filter and the first color compensation layer,
wherein the black matrix is disposed in a boundary area between the transmissive area and the non-transmissive area.

9. The transparent display device according to claim 1, further comprising:
a second color compensation layer disposed between the first color filter and the first color compensation layer,
wherein the second color compensation layer is disposed to cover a portion of an upper surface of the first color filter.

10. The transparent display device according to claim 9,
wherein for the second color compensation layer, a transmittance of light in a wavelength range being equal to or greater than 380 nm and less than 500 nm is greater than a transmittance of light in a wavelength range being equal to or greater 500 nm and less than 780 nm, and
wherein the transmittance of light in the wavelength range being equal to or greater than 380 nm and less than 500 nm is equal to or greater than about 20%.

11. The light emitting display according to claim 1, wherein the first color compensation layer includes a blue color filter.

12. A transparent display device comprising:
a non-transmissive area including a first light emitting area and a second light emitting area;
a transmissive area disposed on one side of the non-transmissive area and configured to transmit light;
a first color filter disposed to correspond to the first light emitting area in the non-transmissive area; and
a first color compensation layer overlapping at least a portion of the transmissive area,
wherein for the first color compensation layer, a transmittance of light in a wavelength range being equal to or greater than 380 nm and less than 500 nm is greater than a transmittance of light in a wavelength range being equal to or greater 500 nm and less than 780 nm, and
wherein the transmittance of light in the wavelength range being equal to or greater than 380 nm and less than 500 nm is equal to or greater than about 20%.

13. The transparent display device according to claim 12, further comprising:
a black matrix disposed to surround the first light emitting area and the second light emitting area.

14. The transparent display device according to claim 12, further comprising:
a second color compensation layer disposed to surround the first light emitting area and the second light emitting area,
wherein for the second color compensation layer, a transmittance of light in a wavelength range being equal to or greater than 380 nm and less than 500 nm is greater than a transmittance of light in a wavelength range being equal to or greater 500 nm and less than 780 nm, and
wherein the transmittance of light in the wavelength range being equal to or greater than 380 nm and less than 500 nm is equal to or greater than about 20%.

15. The transparent display device according to claim 14,
wherein the second color compensation layer transmits light of a same color as the first color filter.

16. The light emitting display according to claim 12, wherein the first color compensation layer includes a blue color filter.

17. A transparent display device comprising:
a substrate including a transmissive area and a non-transmissive area;
a first insulating layer disposed on the substrate;
a bank disposed on the first insulating layer and defining a first light emitting area and a second light emitting area;
a step area disposed at a boundary area between the transmissive area and the non-transmissive area, and disposed by one end of the first insulating layer and one end of the bank; and
a first color compensation layer disposed to overlap the step area, and having a complementary color relationship with light passing through the transmission area,
wherein the step area overlaps the transmissive area.

18. The transparent display device according to claim 17,
wherein for the first color compensation layer, a transmittance of light in a wavelength range being equal to or greater than 380 nm and less than 500 nm is greater than a transmittance of light in a wavelength range being equal to or greater 500 nm and less than 780 nm, and
wherein the transmittance of light in the wavelength range being equal to or greater than 380 nm and less than 500 nm is equal to or greater than 20%.

19. The transparent display device according to claim 17, further comprising:
a counter substrate opposite to the substrate,
wherein the counter substrate includes a first color filter corresponding to the first light emitting area, and
wherein the first color compensation layer is disposed on a same layer as the first color filter.

20. The transparent display device according to claim 19, further comprising:
a second color compensation layer disposed between the first color compensation layer and the first color filter,
wherein the second color compensation layer is disposed to cover a portion of an upper surface of the first color filter, and
wherein the second color compensation layer has a complementary color relationship with light passing through the transmission area.

21. The transparent display device according to claim 19,
wherein the second light emitting area provides a white color light,
wherein the second light emitting area includes:
an upper light emitting area; and
a lower light emitting area apart from the upper light emitting area,
wherein the counter substrate further includes a second color compensation layer pattern overlapped a correspondence area between the upper light emitting area and the lower light emitting area.

22. The transparent display device according to claim 17,
wherein the first color compensation layer is disposed to cover one side surface of the first insulating layer and one side surface of the bank, and
wherein the first color compensation layer is in contact with a portion of an upper surface of the substrate.

23. The light emitting display according to claim 17, wherein the first color compensation layer includes a blue color filter.
